(19) United States
(12) Patent Application Publication
(10) Pub. No.: US 2025/0372367 A1
(43) Pub. Date: Dec. 4, 2025

(54) DEPOSITION AND ETCH OF SILICON-CONTAINING LAYER

(71) Applicant: Lam Research Corporation, Fremont, CA (US)

(72) Inventors: Nuoya YANG, Frisco, TX (US); Yuxi WANG, Beaverton, OR (US); Bo GONG, Sherwood, OR (US); Andrew John MCKERROW, Lake Oswego, OR (US); Ching-Yun CHANG, West Linn, OR (US)

(21) Appl. No.: 18/875,090

(22) PCT Filed: Jun. 26, 2023
(86) PCT No.: PCT/US2023/026231

§ 371 Date: Dec. 13, 2024

Related U.S. Application Data
(60) Provisional application No. 63/367,106, filed on Jun. 27, 2022.
(60) Provisional application No. 63/385,558, filed on Nov. 30, 2022.

(51) Int. Cl. H01L 21/02; C23C 16/24; C23C 16/52; C23C 16/56; H01J 37/32; H01L 21/311

(52) U.S. Cl. CPC H01L 21/0234; C23C 16/24; C23C 16/52; C23C 16/56; H01J 37/32357; H01J 37/32449; H01L 21/02211; H01L 21/0228; H01L 21/31116; H01J 2237/334

(57) ABSTRACT

A silicon-based film is conformally deposited in a feature and controllably etched using remote plasma. The silicon-based film may be an amorphous silicon layer or a doped silicon layer comprising silicon oxide, silicon nitride, silicon carbide, silicon oxycarbide, silicon carbonitride, silicon oxynitride, or silicon oxycarbonitride. The silicon-based film may be partially etched using remote plasma according to a desired depth and geometry by modulating one or more of the following etch parameters: chamber pressure, substrate temperature, exposure time, RF power, gas composition, and relative concentrations of the gas composition. Methods of and apparatuses for depositing silicon-containing films with tunable film composition and density are also provided, where the silicon-containing film is formed by thermal atomic layer deposition or thermal chemical vapor deposition and treating the silicon-containing film with a densifying gas plasma.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor device fabrication processes involve forming silicon-based dielectric films. Silicon-based dielectric films may include films including one element of silicon; or two elements such as silicon oxide, silicon carbide, or silicon nitride; or three elements such as silicon oxynitride, silicon oxycarbide, or silicon carbonitride; or four elements such as silicon oxycarbonitride. Depositing and etching a silicon-based dielectric film according to a target depth and profile can be particularly challenging. Challenges can also include gapfill of high aspect ratio features with the silicon-based dielectric film.

Some deposition of silicon-based dielectric films involves thermal chemical vapor deposition (CVD) and/or thermal atomic layer deposition (ALD). In certain applications, thermal deposition is desired but the deposition conditions may be limited by the use of certain deposition precursors.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

One aspect involves a method of processing a substrate, the method including: conformally depositing a silicon-containing film in one or more recessed features of the substrate, and etching at least a portion of the silicon-containing film to at least one of a desired depth and desired profile by exposing the substrate to a remote plasma.

In various embodiments, the silicon-containing film comprises an amorphous silicon layer. In various embodiments, conformally depositing the silicon-containing film comprises flowing a silicon-containing precursor to adsorb on surfaces of the substrate and thermally decomposing the silicon-containing precursor to form the amorphous silicon layer.

In various embodiments, the silicon-containing film comprises silicon oxide, silicon nitride, silicon carbide, silicon oxycarbide, silicon carbonitride, silicon oxynitride, or silicon oxycarbonitride. In various embodiments, conformally depositing the silicon-containing film comprises: flowing a silicon-containing precursor to adsorb on surfaces of the substrate, thermally decomposing the silicon-containing precursor to form an amorphous silicon layer, and exposing the amorphous silicon layer to plasma to convert the amorphous silicon layer to silicon oxide, silicon nitride, silicon carbide, silicon oxycarbide, silicon carbonitride, silicon oxynitride, or silicon oxycarbonitride.

In various embodiments, conformally depositing the silicon-containing film comprises: depositing the silicon-containing film by thermal ALD or thermal CVD, and treating the silicon-containing film with a densifying gas plasma.

In various embodiments, the remote plasma comprises one or more plasma-activated species comprising radicals of hydrogen, halides, hydrocarbons, fluorocarbons, or combinations thereof. In various embodiments, the one or more plasma-activated species comprise radicals of hydrogen.

In various embodiments, the at least one of the desired depth and desired profile of the etch is based on one or more of the following etch parameters: chamber pressure, substrate temperature, exposure time, gas composition, relative concentrations of the gas composition, and RF power. In various embodiments, the desired depth of the etch is modulated according to the chamber pressure. In various embodiments, the desired depth of the etch is modulated according to the substrate temperature. In various embodiments, the desired depth of the etch is modulated according to the RF power. In various embodiments, the desired profile of the etch is modulated according to the relative concentrations of the gas composition.

In various embodiments, depositing the silicon-containing film and etching at least the portion of the silicon-containing film occur in the same reaction chamber.

In various embodiments, the method further includes: repeating deposition and etch operations to partially fill or completely fill the one or more recessed features of the substrate with a silicon-containing gapfill material.

Another aspect involves a method of processing a substrate, the method including: flowing, into a reaction chamber, a silane-based precursor to adsorb in one or more recessed features of the substrate, where the substrate is at an elevated temperature to thermally decompose the silane-based precursor and conformally deposit an amorphous silicon layer in the one or more recessed features of the substrate. The method further includes generating, in a remote plasma chamber upstream of the reaction chamber, a remote plasma comprising radicals of hydrogen, halides, hydrocarbons, fluorocarbons, or combinations thereof, and exposing, in the reaction chamber, the substrate to the remote plasma to etch at least a portion of a silicon-containing layer in the one or more recessed features to at least one of a desired depth and desired profile by modulating one or more of the following etch parameters: chamber pressure, substrate temperature, exposure time, gas composition of the remote plasma, relative concentrations of the gas composition, and RF power.

In various embodiments, the silicon-containing layer comprises the amorphous silicon layer.

In various embodiments, the silicon-containing layer comprises silicon oxide, silicon nitride, silicon carbide, silicon oxycarbide, silicon carbonitride, silicon oxynitride, or silicon oxycarbonitride.

In various embodiments, the remote plasma comprises radicals of hydrogen.

In various embodiments, the silane-based precursor comprises silane, disilane, or trisilane.

In various embodiments, the method further includes: repeating deposition and etch operations to partially fill or completely fill the one or more recessed features of the substrate with a silicon-containing gapfill material.

Another aspect involves a method of processing a substrate housed in a process chamber, the method including: introducing a silicon-containing precursor and a reactant to the process chamber at a substrate temperature less than about 700° C. to form a silicon-containing film over the substrate without igniting a plasma; after forming the silicon-containing film, performing a plasma treatment operation, the plasma treatment operation comprising: stopping flow of the silicon-containing precursor and the flow of the reactant; introducing a densifying gas into the process chamber; and igniting a plasma to treat the silicon-containing film; and modulating at least one of the silicon-containing precursor, the reactant, or process conditions during the plasma treatment operation to vary at least the composition of or density of the silicon-containing film to form a treated silicon-containing film.

In various embodiments, the plasma treatment operation is performed after the silicon-containing film is formed to a thickness of about 1 Å to about 30 Å, or about 1 Å to about 20 Å.

In various embodiments, the method may also include stopping the plasma treatment operation and introducing the silicon-containing precursor and the reactant to form additional silicon-containing film over the treated silicon-containing film.

In various embodiments, the silicon-containing precursor and reactant are introduced simultaneously.

In various embodiments, the silicon-containing precursor and reactant are introduced in temporally separated pulses.

In various embodiments, the method may also include purging the process chamber between forming the silicon-containing film and performing the plasma treatment operation.

In various embodiments, the silicon-containing film is selected from the group consisting of silicon carbide, silicon oxycarbide, silicon oxynitride, silicon oxycarbonitride, silicon carbonitride, and combinations thereof.

In various embodiments, the method further includes etching at least a portion of the silicon-containing film by exposing the substrate to a remote plasma.

In various embodiments and in some of any of the above embodiments, the plasma is generated in situ.

In various embodiments and in some of any of the above embodiments, the first and second plasmas are ignited using a single frequency plasma generator.

In various embodiments and in some of any of the above embodiments, the plasma is ignited using a dual frequency plasma generator.

In various embodiments and in some of any of the above embodiments, the reactant is selected from the group consisting of oxygen, ozone, peroxides, nitrous oxide, nitric oxide, nitrogen, ammonia, hydrazines, and combinations thereof.

In various embodiments and in some of any of the above embodiments, the density of the silicon-containing film is at least about 2.0 g/cm³ to about 2.6 g/cm³.

In various embodiments and in some of any of the above embodiments, the plasma treatment operation is performed at a temperature of less than about 700° C. In various embodiments and in some of any of the above embodiments, the plasma treatment operation is performed at a temperature of less than about 650° C.

In various embodiments and in some of any of the above embodiments, the silicon-containing film is formed in a feature having an aspect ratio of at least about 5:1.

In various embodiments and in some of any of the above embodiments, the silicon-containing film is deposited using thermal atomic layer deposition.

In various embodiments and in some of any of the above embodiments, the silicon-containing film is deposited using thermal chemical vapor deposition.

Another aspect involves an apparatus for processing substrates, the apparatus including: one or more process chambers, each process chamber including a chuck; one or more gas inlets into the process chambers and associated flow-control hardware; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause formation of a silicon-containing film over the substrate without igniting a plasma at a substrate temperature of less than about 700° C.; and cause the silicon-containing film to be treated using an densifying gas plasma.

These and other aspects are described further below with reference to the drawings.

### BRIEF DESCRIPTION OF THE DRAWINGS

FIGS. 1A-IC show cross-sectional schematic illustrations of a feature of an example substrate undergoing gapfill using directional etch in a dep-etch-dep process.

FIGS. 2A-2C show cross-sectional schematic illustrations of a feature of an example substrate undergoing gapfill using inhibition chemistry in a dep-etch-dep process.

FIG. 3 illustrates a flow chart of an example method of performing deposition and etch in a feature of a substrate according to some implementations.

FIGS. 4A-4B show cross-sectional schematic illustrations of a feature of an example substrate being partially etched to a shallow depth using remote plasma according to some implementations.

FIGS. 5A-5B show cross-sectional schematic illustrations of a feature of an example substrate being partially etched to a deep depth using remote plasma according to some implementations.

FIGS. 6A-6B show cross-sectional schematic illustrations of a feature of an example substrate being partially etched at a top surface using remote plasma according to some implementations.

FIGS. 7A-7C show cross-sectional schematic illustrations of a feature of an example substrate undergoing gapfill in a dep-etch-dep process according to some implementations.

FIGS. 8A and 8B are process flow diagrams depicting operations for example methods that may be performed in accordance with certain disclosed implementations.

FIG. 9 is a timing sequence diagram showing an example of a method in accordance with certain disclosed implementations.

FIG. 10 is an FTIR spectra for a film deposited using a deposition precursor with and without plasma treatment.

FIG. 11 is an FTIR spectra for a film deposited using a deposition precursor and oxygen gas with and without plasma treatment.

FIG. 12 illustrates a schematic diagram of an example plasma processing apparatus with a remote plasma source according to some implementations.

FIG. 13 illustrates a schematic diagram of an example plasma processing apparatus with a remote plasma source according to some implementations.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

Substrates may include “features” or “trenches.” “Features” as used herein may refer to non-planar structures of a substrate, typically a surface being modified in a semiconductor device fabrication operation. Examples of features, which may also be referred to as “negative features” or “recessed features,” include trenches, holes, vias, gaps, recessed regions, and the like. These terms may be used interchangeably in the present disclosure. One example of a feature is a hole or via in a semiconductor substrate or in a layer on the substrate. Another example is a trench in a substrate or layer. A feature typically has an aspect ratio (depth to lateral dimension). A feature may be characterized by one or more of narrow and/or re-entrant openings, constrictions within the feature, and high aspect ratios. A feature having a high aspect ratio can have a depth to lateral dimension aspect ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1. In various embodiments, the feature may have an under-layer, such as a barrier layer or adhesion layer. Non-limiting examples of under-layers include dielectric layers and conducting layers, e.g., silicon oxides, silicon nitrides, undoped silicon carbides, oxygen-doped silicon carbides, nitrogen-doped silicon carbides, metal oxides, metal nitrides, metal carbides, and metal layers.

Features of a substrate can be of various types. In some embodiments, a feature can have straight sidewalls, positively sloped sidewalls, or negatively sloped sidewalls. In some embodiments, a feature can have sidewall topography or sidewall roughness, which may occur as a result of an etch process to form the feature. In some embodiments, a feature can have a feature opening that is greater at the top of the feature than at the bottom, or a feature can have a feature opening that is greater at the bottom of the feature than at the top.

Semiconductor manufacturing processes often involve fabrication of silicon-containing films, such as silicon carbonitride, silicon oxycarbonitride, silicon carbide, and silicon oxynitride. Such films are sometimes deposited onto patterned substrates to form conformal films for various applications. Sometimes such films are deposited in a furnace. As devices shrink and technologies become more advanced, higher quality, dense, and more conformal films are desired. Certain silicon-containing films may be deposited into high aspect ratio features on substrates. In some instances, deposition is performed thermally for a variety of reasons, including but not limited to reducing or eliminating damage to existing structures and/or materials on the substrate.

One technique for depositing films is chemical vapor deposition (CVD), which may be thermal, or may be plasma-enhanced (e.g., plasma-enhanced CVD, sometimes referred to as PECVD). In CVD, the deposition reactants are reacted together, often in gas phase or vapor phase, over a substrate surface, thereby causing formation of a film on the substrate.

Another technique for depositing films is atomic layer deposition (ALD), which also may be thermal, or may be plasma-enhanced (e.g., plasma-enhanced ALD, sometimes referred to as PEALD). ALD is a technique that deposits thin layers of material using sequential self-limiting reactions. Unlike CVD, ALD processes use surface-mediated deposition reactions to deposit films on a layer-by-layer basis. As an example, a thermal ALD cycle may include the following operations: (i) delivery/adsorption of a precursor, (ii) purging of precursor from the chamber, (iii) delivery of a second reactant, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as a carbon-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation, such as heat, is applied. In some embodiments, the source of activation is only applied when the second precursor is introduced. The exposure to the second reactant and the deposition precursor may be separated temporally, that is, one occurs after another but are not performed simultaneously. After exposure to the second reactant, the flow of the second reactant may be stopped and chamber may then be evacuated again to remove unbound second reactant molecules. As described above, in some embodiments the chamber may not be completely evacuated. Additional ALD cycles may be used to build film thickness.

In PEALD implementations, the methods include plasma activation during exposure to the second reactant. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

While ALD processes may be used to deposit certain films, certain processes involve using halogen-containing precursors, which may limit the process conditions in which the film can be deposited. For example, in some embodiments, deposition may occur only at temperatures of greater than about 700° C. or greater than about 650° C. due to thermodynamic constraints.

Provided herein are methods and apparatuses for depositing silicon-containing dielectric films by thermal ALD and/or CVD with a halogen-free deposition precursor and tunable film composition and densification. Silicon-containing films deposited using certain disclosed embodiments are high quality films. Silicon-containing films are deposited on a substrate, which may be a silicon wafer, e.g., a 200-mm wafer, a 300-mm wafer, or a 450-mm wafer, including wafers having one or more layers of material, such as dielectric, conducting, or semi-conducting material deposited thereon. Non-limiting examples of layers that may be deposited on a substrate include dielectric layers and conducting layers, e.g., silicon oxides, silicon nitrides, silicon carbides, metal oxides, metal nitrides, metal carbides, and metal layers. The substrate may be patterned to form features having an aspect ratio between about 1:1 and about 60:1, or greater than about 1.5:1, or greater than about 4:1, or between about 1.5:1 and 60:1, or between about 1.5:1 and 40:1, or between about 1.5:1 and 20:1, such as about 5:1.

Films deposited in accordance with certain disclosed embodiments may be conformal. Conformality may be determined by the step coverage. “Step coverage” as used herein is calculated by dividing the average thickness of the deposited film on the sidewall by the average thickness of the deposited film at the top of the feature and multiplying it by 100 to obtain a percentage. Films deposited using certain disclosed embodiments can achieve a step coverage of about 70% to about 120% for features having an aspect ratio of about 1:5 to about 1:50.

Methods described herein are performed at temperatures less than about 700° C., such as less than about 650° C., between about 250° C. and about 350° C., such as about 275° C. It will be understood that temperatures as described herein may refer to the temperature at which a pedestal holding the substrate may be set at. The terms “substrate temperature,” “pedestal temperature,” and “temperature” may all refer to temperatures at which a pedestal is set at. The temperature may also depend on the pressure of the chamber in which the semiconductor substrate is housed. Methods may also be performed in a process chamber having a chamber pressure less than about 10 Torr, such as between about 2 Torr and about 10 Torr.

Manufacture of semiconductor devices typically involves forming one or more silicon-based thin films on a semiconductor substrate in an integrated fabrication process. Silicon-based thin films may include doped or undoped silicon oxide, doped or undoped silicon nitride, or doped or undoped silicon carbide. Technology nodes are continually shrinking in the integrated circuit manufacturing industry. With each technology node, device geometries also shrink, and pitch becomes smaller. High aspect ratio gaps in such technology nodes may need to be filled with insulating material, such as insulating material with a low dielectric constant (low-k). Semiconductor integration operations may involve filling high aspect ratio gaps with low-k dielectric materials. This is the case for shallow trench isolation, inter-metal dielectric layers, passivation layers, and the like. In another example, as device features shrink laterally, unwanted conductive coupling may occur as conductive materials get closer and closer, which can lead to parasitic capacitance, delay in signal propagation, and signal crosstalk due to capacitive effects. Low-k materials as the interlayer dielectric (ILD) of conductive interconnects may reduce parasitic capacitance, signal delay, and signal crosstalk. Some applications, including fin field effect transistor (finFET) structures and dynamic random-access memory (DRAM) bit structures, require low-k materials as sidewall spacer materials.

Silicon nitride is often used as an insulating material in many integrated circuit applications because of its step coverage, thermal stability, etch-ability and etch resistance, and high breakdown voltages.

Silicon oxide has a lower dielectric constant, which is about 4.0, and can provide a significant reduction in capacitance as an interlayer dielectric of conductive interconnects.

Silicon carbide materials, including doped and undoped silicon carbide materials, may serve as insulating materials in integrated circuit applications that provide not only a low dielectric constant, but also step coverage, thermal stability, wet etch resistance, dry etch selectivity to oxide/nitride, and high breakdown voltages. For example, incorporation of oxygen atoms and/or nitrogen atoms may tune the properties of silicon carbide materials. In some embodiments, an oxygen doped silicon carbide film can serve as an insulating material in integrated circuit applications that provides a low dielectric constant, wet etch resistance to survive device integration operations, and dry etch selectivity to oxide/nitride.

Forming high-quality silicon-based thin films may have certain challenges, such as providing films with excellent step coverage, low dielectric constants, and/or high breakdown voltages etc. Once a silicon-based thin film is formed with desired properties and composition, additional challenges may exist to conformally deposit the silicon-based thin film in high aspect ratio features. Conformal deposition may be desirable in gapfill of the high aspect ratio features. Semiconductor fabrication processes often involve gapfill processes or dielectric gapfill processes. Typically, CVD and/or ALD methods are used to fill features. Conventional techniques, however, often result in formation of undesirable seams or voids within the feature. In some cases, the presence of seams and/or voids in gapfill may lead to high resistance, contamination, loss of filled materials, degraded performance, and even device failure.

To avoid formation of seams and voids during gapfill, features may be filled by bottom-up filling processes. Bottom-up filling may be done with silicon oxide films but is more challenging with other silicon-based films. Silicon-based films may be deposited in features using conventional vapor deposition techniques such as CVD and ALD. As the aspect ratio of features increases, mass transport limitations of CVD gas phase reactions may cause “bread-loafing” deposition effects that show thicker deposition at top surfaces and thinner deposition at recessed surfaces, which causes the top of a feature opening to close before the feature can be completely filled. Unlike CVD processes, ALD processes use surface-mediated deposition reactions to deposit films on a layer-by-layer basis, and such films are typically conformal. Although ALD can deposit highly conformal films, deposition of films into high aspect ratio features can be difficult. The step coverage and uniformity of film along the sidewall depends on, for example, transport of the deposition precursor, reactant ions and/or radicals, and byproducts. As the lateral dimension of the feature narrows, transport and diffusion of the deposition precursor and any reactant species becomes progressively more difficult in the feature. Thus, the top of the feature is exposed to more precursor and reactant species and the bottom of the feature is exposed to fewer precursor and reactant species due to diffusion limitations. This can result in formation of seams and voids in high aspect ratio features. Various approaches may be taken in gapfill of features with silicon-containing material that avoid the formation of seams and/or voids.

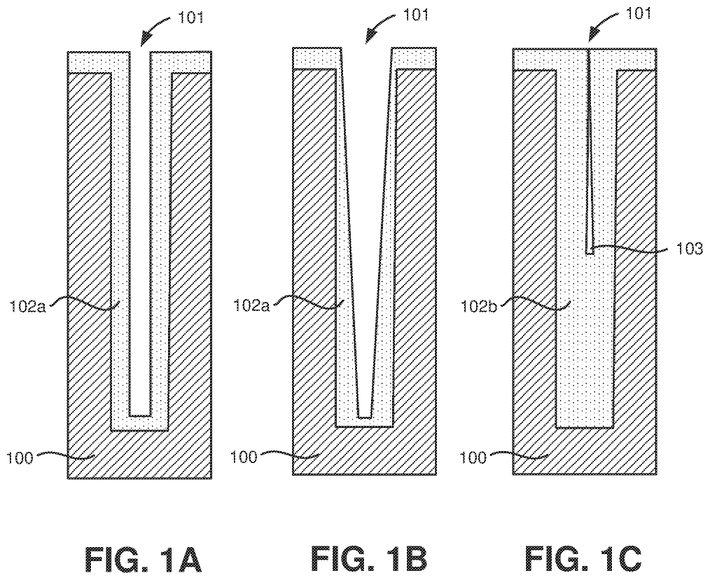

FIGS. 1A-1C show cross-sectional schematic illustrations of a feature of an example substrate undergoing gapfill using directional etch in a dep-etch-dep process. Dep-etch-dep (deposition, etch, deposition) techniques involve deposition of gapfill material, followed by etching some of the gapfill material back to open the feature opening, and followed by re-depositing the gapfill material to complete the gapfill or at least advance the gapfill process. FIG. 1A shows an example of a feature 101 of a substrate 100 where a gapfill material 102a is deposited in the feature 101. The gapfill material 102a may be deposited conformally along a top surface, sidewalls, and bottom surface of the feature 101. In some embodiments, the gapfill material 102a may be deposited using ALD.

FIG. 1B shows an example of the feature 101 of the substrate 100 where the gapfill material 102a is etched back. For example, the gapfill material 102a can be etched back to form a tapered profile. Thus, more of the gapfill material 102a is removed near the top of the feature 101 than at the bottom of the feature 101. The etch is configured to reshape the gapfill material 102a so that more material can be filled in the feature 101. That way, the profile of the feature 101 does not limit the diffusion of precursor and/or reactant species to reach the bottom and sidewalls of the feature 101 during a subsequent deposition process.

To reduce or eliminate the presence of voids and seams in gapfill, different types of etches can be applied between deposition cycles. Etch conditions and chemistries can be tuned to provide a nonconformal etch. In some cases, the nonconformal etch preferentially removes more gapfill material 102a near a top surface of the feature 101 than at a bottom surface of the feature 101. Etch chemistries often include fluorine-containing species, where fluorine-containing etchants can include xenon difluoride (XeF₂), molecular fluorine (F₂), or nitrogen trifluoride (NF₃). Other fluorine-containing etchants can include tetrafluoromethane (CF₄), fluoromethane (CH₃F), difluoromethane (C₂H₆), tetrafluoroethylene (C₂F₄), hexafluoroethane (C₂F₆), octafluoropropane (C₃F₈), and sulfur hexafluoride (SF₆). In certain embodiments, a fluorine-based etch may be a plasma etch so that radicals and/or ions of fluorine-containing species may react with the gapfill material 102a to remove the gapfill material 102a. Fluorine-based etching may be controlled to etch a silicon-based film and to re-shape a profile of the etched silicon-based film.

FIG. 1C shows an example of the feature 101 of the substrate 100 where gapfill material 102b is deposited to fill or substantially fill the feature 101. Though deposition of the gapfill material 102b may result in the formation of a void 103, a size of the void 103 may be minimized by interrupting deposition with one or more etch operations. The gapfill material 102b may be the same as the gapfill material 102a, where the feature 101 is filled or substantially filled with the combined gapfill material 102a, 102b. In some embodiments, one or both of the gapfill material 102a and the gapfill material 102b includes a silicon-based dielectric material such as silicon oxide, silicon nitride, silicon carbide, silicon oxycarbide, silicon carbonitride, silicon oxynitride, and silicon oxycarbonitride.

Fluorine-based etchants, such as radicals of fluorine, may chemically react with silicon in a silicon-based film to selectively remove the silicon-based film. Thus, a fluorine-based etch is commonly used to etch silicon-containing layers. However, a fluorine-based etch may be undesirable for a number of reasons. First, fluorine-based chemistries may not be compatible with certain materials and layers in a semiconductor fabrication process, resulting in unwanted reactions with fluorine-containing species. Second, fluorine-based etchants may leave residue on sidewalls and other surfaces of a patterned substrate. Fluorine residue may be undesirably incorporated in subsequent processing steps. Third, fluorine-based plasmas may leave etched surface roughness, which can adversely impact device performance.

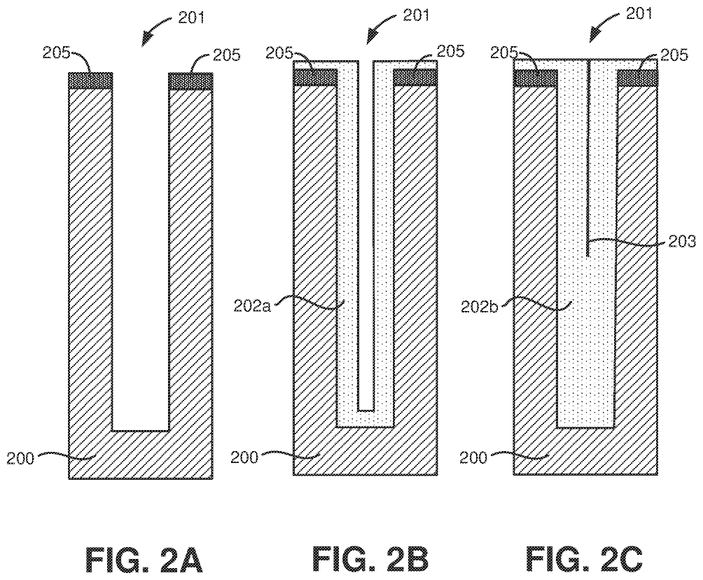

FIGS. 2A-2C show cross-sectional schematic illustrations of a feature of an example substrate undergoing gapfill using inhibition chemistry in a dep-etch-dep process. Inhibition chemistry can be used so that gapfill material grows or otherwise forms in a feature in a topographically different manner. For example, an inhibitor can react with a material and create a passivated surface that inhibits growth. A surface of a substrate can be more passivated in field and upper regions of a feature and less passivated as a distance into the feature increases. As a result, deposition at a top of the feature is selectively inhibited and deposition in lower portions of the feature can proceed with less inhibition or without being inhibited. FIG. 2A shows an example of a feature 201 of a substrate 200 where at least a field region and upper regions of the feature 201 are exposed to a reactant that inhibits deposition/growth of gapfill material. The reactant reacts with a substrate material to form a passivated layer 205 on the substrate 200. By way of an example, nitrogen gas (N₂) or ammonia (NH₃) may be used to form the passivated layer 205 that is composed of a nitride. Gapfill material, such as silicon dioxide (SiO₂), nucleates at a slower rate on nitride surfaces.

FIG. 2B shows an example of the feature 201 of the substrate 200 where gapfill material 202a is deposited in the feature 201. The gapfill material 202a may be deposited along a top surface, sidewalls, and a bottom surface of the feature 201. The passivated layer 205 selectively inhibits deposition/growth of the gapfill material 202a in the field region and upper regions of the feature 201 so that more of the gapfill material 202a is deposited in the sidewalls and bottom surface of the feature 201 than in the field region and upper regions of the feature 201.

FIG. 2C shows an example of the feature 201 of the substrate 200 where gapfill material 202b is deposited to fill or substantially fill the feature 201. Deposition of the gapfill material 202b may result in the formation of a void 203, but the void 203 may be smaller by virtue of the inhibition chemistry promoting bottom-up filling in the feature 201. The gapfill material 202b may be the same as the gapfill material 202a, where the feature 201 is filled or substantially filled with the combined gapfill material 202a, 202b. In some embodiments, one or both of the gapfill material 202a and the gapfill material 202b includes a silicon-based dielectric material such as silicon oxide, silicon nitride, silicon carbide, silicon oxycarbide, silicon carbonitride, silicon oxynitride, and silicon oxycarbonitride.

While inhibition chemistry may mitigate the formation of seams and voids, inhibition chemistries are generally limited to certain types of chemistries and processes. In other words, different processes require different inhibition chemistries. Other than silicon oxide films, many inhibition chemistries are often not suitable for limiting deposition/growth of silicon nitride, silicon carbide, silicon oxycarbide, silicon carbonitride, silicon oxynitride, and silicon oxycarbonitride films. In some cases, certain inhibition chemistries may not be suitable with particular deposition techniques such as remote plasma CVD. Thus, application of inhibition chemistry in gapfill may be limited to certain gapfill chemistries, deposition techniques, and even film properties.

Provided herein are methods and apparatuses that relate to controllably etching a silicon-based film using a remote plasma etch, where the silicon-based film is conformally deposited in a high aspect ratio feature of a substrate. The geometry and depth of the etch can be controlled by adjusting process parameters such as pressure, temperature, exposure time, gas flow, gas composition, and plasma power, among other process parameters. In some implementations, the remote plasma etch uses a remote plasma gas flow comprising one or more gas species, where the one or more gas species includes hydrogen (H₂). In some implementations, the silicon-based film includes amorphous silicon (a-Si), or the silicon-based film includes silicon oxide, silicon nitride, silicon carbide, silicon oxycarbide, silicon carbonitride, silicon oxynitride, or silicon oxycarbonitride. After conformally depositing the silicon-based film, the silicon-based film is exposed to remote plasma to controllably etch at least some of the silicon-based film. In some embodiments, the remote plasma removes portions of the silicon-based film at top and sidewall regions of the silicon-based film to achieve a certain depth and/or profile. In some cases, conformal deposition and controllable etch operations are repeated to fill the high aspect ratio feature in a gapfill process.

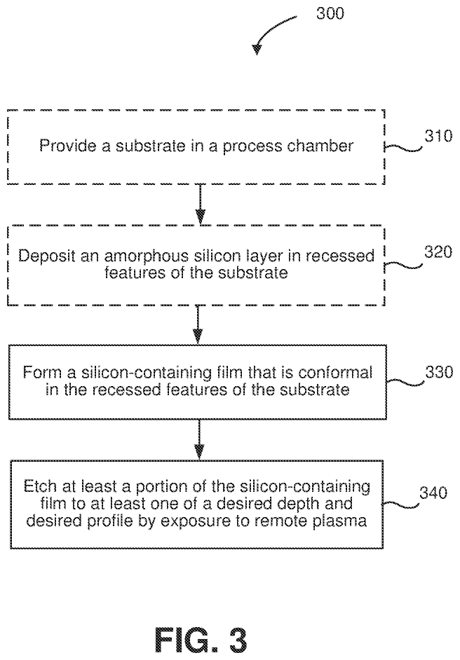

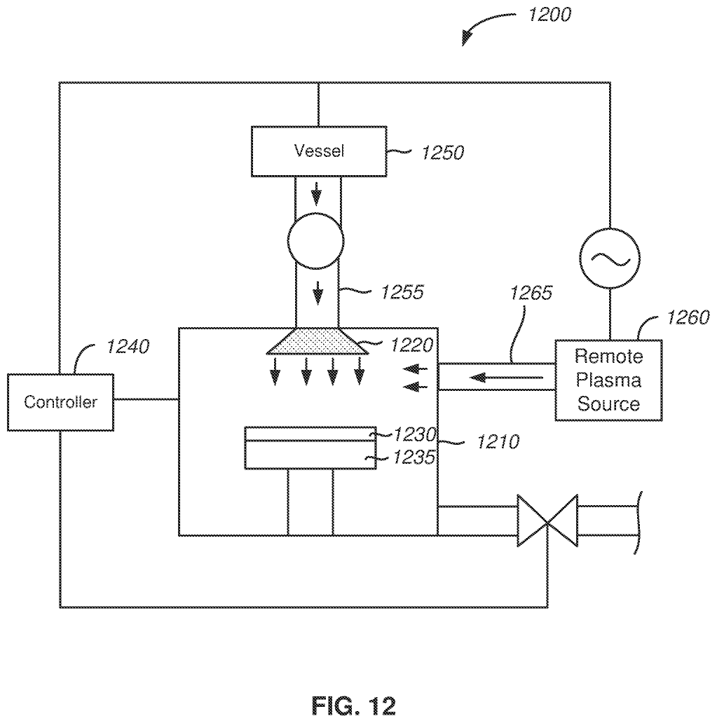

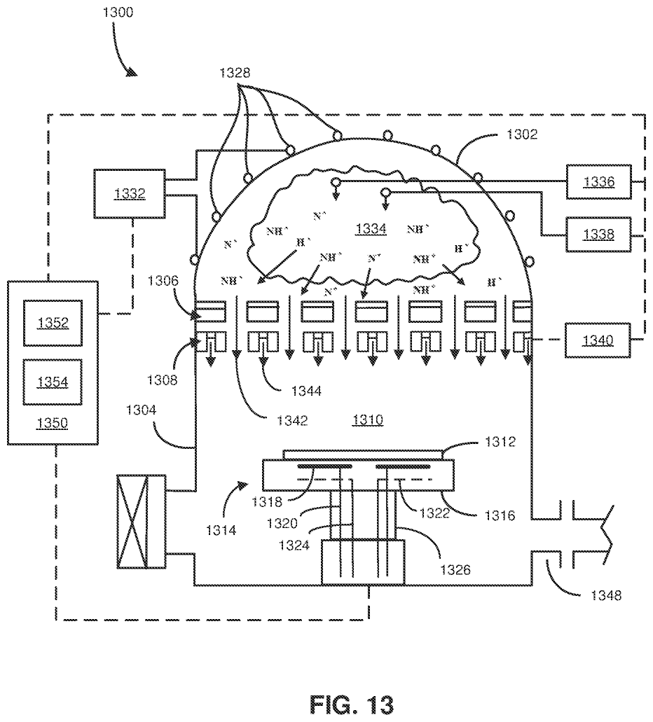

FIG. 3 illustrates a flow chart of an example method of performing deposition and etch in a feature of a substrate according to some implementations. The operations of a process 300 may be performed in different orders and/or with different, fewer, or additional operations. One or more operations of the process 300 may be performed using a substrate processing apparatus shown in FIG. 12 or 13. In some implementations, the operations of the process 300 may be implemented, at least in part, according to software stored in one or more non-transitory computer readable media.

At block 310 of the process 300, a substrate is optionally provided in a process chamber. The substrate may be supported on a substrate support or pedestal in the process chamber. The substrate can be any wafer, semiconductor wafer, partially fabricated integrated circuit, printed circuit board, display screen, or other appropriate workpiece. The substrate may be a patterned substrate having features. The one or more features may be high aspect ratio features, where the high aspect ratio features have a depth to width aspect ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1. For some embodiments, the one or more recessed features include high aspect ratio trenches in 3D-NAND or logic device. Prior to or after providing the substrate in the process chamber, optionally the substrate may be cleaned prior to depositing and etching a silicon-containing layer on the substrate. For example, diluted hydrogen fluoride (HF) may be used to remove any contaminants or thin oxide layer on the substrate.

The process chamber provides an enclosed space for depositing a silicon-containing layer on the substrate. In some cases, the process chamber is also used for etching the silicon-containing layer with remote plasma. Using the same process chamber for deposition and etch minimizes substrate transfers and limits air breaks in between operations. Chamber walls in the process chamber may be fabricated from stainless steel, aluminum, plastic, ceramic, or other suitable material. The process chamber may include a substrate support (e.g., pedestal or electrostatic chuck) on which the substrate is supported. In some embodiments, the process chamber may include one or more heating elements for controlling a temperature of the substrate, where the one or more heating elements may be infrared (IR) lamps light-emitting diodes (LEDs), or resistive heaters located in the substrate support. The process chamber may include one or more gas lines for delivering gas into the process chamber. For example, the one or more gas lines may include a showerhead for supplying process gases towards the substrate in the process chamber. In some implementations, the process chamber may be coupled to a plasma-generating chamber separate from the process chamber. The plasma-generating chamber (e.g., remote plasma chamber) may be an inductively-coupled plasma (ICP) reactor, a transformer-coupled plasma (TCP) reactor, or a capacitively-coupled plasma (CCP) reactor. In some cases, the process chamber further includes one or more gas outlets for exhausting gases, which may or may not be coupled to a vacuum pump to maintain a desired pressure within the process chamber. The process chamber for depositing a silicon-containing film (e.g., amorphous silicon layer) may be the same for etching the silicon-containing film.

At block 320 of the process 300, an amorphous silicon layer is optionally deposited in recessed features of the substrate. Amorphous silicon (a-Si), as opposed to crystalline silicon, is non-crystalline and lacks long-range order. Techniques for depositing an amorphous silicon layer may include CVD, PECVD, ALD, PEALD, or other suitable deposition technique. In some embodiments, the amorphous silicon layer is deposited by CVD via a thermal decomposition process. The thermal decomposition process is initiated by activation of precursor gas species at elevated temperatures, where the precursor gas species breaks down thermally into atoms and/or molecules for deposition by CVD.

In some embodiments, a thickness of the amorphous silicon layer can be controlled according to a predetermined deposition time to achieve a desired thickness. In some embodiments, the deposition time can be between about 5 seconds and about 500 seconds, or between about 10 seconds and about 200 seconds. In some embodiments, a desired thickness of the amorphous silicon layer can be between about 0.5 nm and about 50 nm, or between about 1 nm and about 20 nm. The deposition time can correspond to the desired thickness of the amorphous silicon layer. The thickness may be controlled to enable sufficient penetration of radicals and/or ions in the amorphous silicon layer from a subsequent remote plasma etch or plasma treatment.

For some embodiments, deposition of the amorphous silicon layer can occur by flowing one or more silicon-containing precursors into the process chamber towards the substrate. The silicon-containing precursors are transported to the substrate surface where they are adsorbed by the substrate to form a highly conformal amorphous silicon layer. In some embodiments, forming an amorphous silicon layer by CVD may necessitate controlling the deposition pressure ranging from 0.1 Torr to 30 Torr or from 0.5 Torr and about 10 Torr. Substrate temperature during amorphous silicon layer deposition may be controlled to be between about 300° C. and about 700° C. or between about 400° C. and about 650° C. After deposition, a step coverage for the amorphous silicon layer may be at least about 85%. In some embodiments, a step coverage may be at least about 90% or at least about 95%.

For some embodiments in CVD or PECVD, silicon-containing precursors may be continuously delivered to the substrate until a desired thickness is obtained. In other embodiments in ALD or PEALD, an amorphous silicon layer may be formed by repeating: (1) pulsing one or more silicon-containing precursors for a predetermined time, followed by (2) purging excess precursors. In some embodiments, the amorphous silicon layer may not include long-range order, instead, the amorphous silicon layer may have a continuous random network of silicon atoms.

As described earlier, the amorphous silicon layer may be highly conformal. Without being limited by any theory, silicon-containing precursors having low sticking coefficients may be capable of producing highly conformal amorphous silicon layers. “Sticking coefficient” is a term used to describe a ratio of the number of adsorbate species (e.g., fragments or molecules) that adsorb/stick to a surface compared to a total number of species that impinge upon that surface during the same period of time. The symbol S_{c} is sometimes used to refer to the sticking coefficient. The value of S_{c} is between 0 (meaning that none of the species stick) and 1 (meaning that all of the impinging species stick). Various factors affect the sticking coefficient including the type of impinging species, surface temperature, surface coverage, structural details of the surface, and the kinetic energy of the impinging species. Certain species are inherently more “sticky” than others, making them more likely to adsorb onto a surface each time the species impinges on the surface. These more sticky species have greater sticking coefficients (all other factors being equal). In some cases, the sticking coefficient of the precursors (at the relevant deposition conditions) may be about 0.05 or less, for example about 0.001 or less.

In some embodiments, silicon-containing precursors may include at least one or more Si—Si bonds and/or one or more Si—H bonds. Silicon-containing precursors suitable for use in accordance with disclosed embodiments may include polysilanes (H₃Si—(SiH₂)ₙ—SiH₃), where n≥0. Examples of silanes are silane (SiH₄), disilane (Si₂H₆), trisilane (Si₃H₈), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. In some embodiments, the one or more silicon-containing precursors include silane, disilane, or trisilane.

In some embodiments, silicon-containing precursors may also include a halosilane. A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursors may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, diisopropylamino silane, di-sec-butyl amino silane, and the like. A further example of an aminosilane is trisilylamin (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; 1-dimethylamino-1,1,5,5,5-pentamethyl disiloxane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In addition to the precursor gas, an inert carrier gas or diluent gas can be flowed to the substrate. Examples of an inert carrier gas or diluent gas include but not limited to helium (He), neon (Ne), argon (Ar), krypton (Kr), xenon (Xe), and nitrogen (N2). In some embodiments, a gas mixture of one or more source gases and one or more of the inert carrier gas or diluent gas may be provided in the remote plasma source.

By way of an example, the one or more silicon-containing precursors include silane, disilane, trisilane, or other silane-based precursor. The silane-based precursor may be flowed into the process chamber and adsorbed on exposed surfaces of the substrate. The silane-based precursor may thermally decompose to form the amorphous silicon layer under certain CVD operating conditions (e.g., 400° C.-650° C., 0.1-30 Torr). Thermal decomposition breaks down the silane-based precursor into atoms and/or molecules for deposition on the surface of the substrate at elevated temperatures. Plasma-based deposition processes may lead to non-conformal deposition of amorphous silicon, but thermal decomposition of silane-based precursors at sufficiently high temperatures provides highly conformal deposition of amorphous silicon.

At block 330 of the process 300, a silicon-containing film is formed that is conformal in the recessed features of the substrate. In some embodiments, the silicon-containing film is the amorphous silicon layer. Thus, formation of the silicon-containing film that is conformal in the recessed features of the substrate at block 330 is accomplished already at block 320 by deposition of the amorphous silicon layer. In some other embodiments, the silicon-containing film comprises two elements, three elements, four elements, or five or more elements. For example, the silicon-containing layer includes silicon oxide, silicon nitride, silicon carbide, silicon oxycarbide, silicon oxynitride, silicon carbonitride, or silicon oxycarbonitride. Formation of a multi-element silicon-containing film can occur by incorporating dopants (other than hydrogen) into the amorphous silicon layer deposited at block 320, thereby converting the amorphous silicon layer into the multi-element silicon-containing film at block 330. Alternatively, formation of the multi-element silicon-containing film can occur without necessarily depositing the amorphous silicon layer at block 320. In such instances, the multi-element silicon-containing film is conformally deposited by CVD, PECVD, ALD, PEALD, or other suitable deposition technique. In one example, a silicon-carbon-containing film may be deposited on the substrate by remote plasma CVD. In another example, the multi-element silicon-containing film is conformally deposited by thermal ALD or thermal CVD, and subsequently treating the silicon-containing film with a densifying gas plasma.

In instances where the silicon-containing film is formed by conversion of the amorphous silicon layer, the amorphous silicon layer may be exposed to a gas plasma flow. The gas plasma flow may contain one or more gas species comprising an oxygen-containing reactant such as oxygen (O₂), ozone (O₃), carbon monoxide (CO), carbon dioxide (CO₂), nitrous oxide (N₂O), or nitrogen dioxide (NO₂), carbon-containing reactant such as acetylene (C₂H₂), ethylene (C₂H₄) or propene (C₃H₆), hydrogen-containing reactant such as hydrogen (H₂) or methane (CH₄), or nitrogen-containing reactant such as nitrogen (N₂), ammonia (NH₃), diazene (N₂H₂), hydrazine (N₂H₄), or mixtures thereof. As such, the gas plasma flow may include hydrogen radicals (H*), nitrogen radicals (N*), oxygen radicals (O′), carbon radicals (C*), amine radicals (NH*, NH₂*), or combinations thereof. In some embodiments, the gas plasma flow is a remote gas plasma flow. In some instances where the silicon-containing film is formed by conversion of the amorphous silicon layer, the amorphous silicon layer may be exposed to elevated temperatures with one or more gas species flowing to the substrate, where elevated temperatures may be between about 200° C. and about 650° C.

In instances where the silicon-containing film is formed by CVD, PECVD, ALD, PEALD, or other suitable deposition technique without conversion of an amorphous silicon layer, silicon-containing precursors may react in the gas phase to deposit the silicon-containing film. The silicon-containing precursors may react with one or more reactants in the gas phase to deposit the silicon-containing film. In some embodiments, the one or more reactants may include an oxygen-containing reactant such as oxygen, ozone, carbon monoxide, carbon dioxide, nitrous oxide, nitrogen dioxide, or mixtures thereof. In some embodiments, the one or more reactants may include a carbon-containing reactant such as acetylene, methane, ethylene, propene, or mixtures thereof. In some embodiments, the one or more reactants may include a nitrogen-containing reactant such as nitrogen, ammonia, diazene, hydrazine, or mixtures thereof. The silicon-containing precursors may have one or more silicon-hydrogen (Si—H) bonds and/or one or more silicon-silicon (Si—Si) bonds. In some embodiments, the silicon-containing precursors may have one or more silicon-carbon (Si—C) bonds, one or more silicon-oxygen (Si—O) bonds, and/or one or more silicon-nitrogen (Si—N) bonds.

The silicon-containing film may be formed with excellent step coverage in the recessed features of the substrate. Step coverage may be calculated by comparing the average thickness of a deposited film on a bottom, sidewall, or top of a feature against the average thickness of the deposited film on another part of the feature. For example, step coverage may be calculated by dividing the average thickness of the deposited film on the sidewall against the average thickness of the deposited film at the top of the feature, and multiplying by 100 to obtain a percentage. In some embodiments, a step coverage for the silicon-containing film may be at least about 85%. In some embodiments, a step coverage may be at least about 90% or at least about 95%. Deposition of a silicon-containing film with excellent step coverage along sidewalls of recessed features can create vertical structures.

In some cases, the silicon-containing film may be conformally deposited in the recessed features using remote plasma CVD such as remote hydrogen plasma CVD. The silicon-containing film may be formed by flowing silicon-containing precursors into the process chamber via a first gas outlet and introducing hydrogen radicals generated from a remote plasma source into the process chamber via a second gas outlet. The first gas outlet may be located downstream from the second gas outlet. The hydrogen radicals react with the silicon-containing precursors in an environment adjacent to the substrate to deposit the silicon-containing film. The Si—H bonds and/or Si—Si bonds are selectively broken by the hydrogen radicals and serve as reactive sites for forming bonds between silicon-containing precursors. The broken bonds can also serve as sites for cross-linking during or after deposition. Bonding at the reactive sites and cross-linking can form a primary backbone or matrix in the resulting silicon-containing film. In some implementations, the hydrogen radicals are in a low energy state or ground state upon reacting with the silicon-containing precursors in the environment adjacent to the substrate. The process conditions may be controlled and the plasma processing apparatus may be designed so that the hydrogen radicals relax from an excited state to a low energy or ground state upon reacting with the silicon-containing precursors. That way, the hydrogen radicals may selectively break Si—H and Si—Si bonds while generally preserving Si—O, Si—N, and Si—C bonds. In some implementations, the hydrogen radicals may be delivered with inert gas such as argon (Ar), helium (He), neon (Ne), krypton (Kr), or xenon (Xe). In some implementations, one or more co-reactants may be flowed into the process chamber to react with the silicon-containing precursors to increase or decrease a carbon, oxygen, or nitrogen content of the silicon-containing film. Details regarding remote hydrogen plasma CVD processes for deposition of silicon-containing films are found in U.S. Pat. No. 10,325,773 to Varadarajan et al., entitled “CONFORMAL DEPOSITION OF SILICON CARBIDE FILMS,” filed Feb. 6, 2015, U.S. patent application Ser. No. 16/044,357 to Weimer et al., entitled “CONFORMAL DEPOSITION OF SILICON CARBIDE FILMS USING HETEROGENEOUS PRECURSOR INTERACTION,” filed Jul. 24, 2018, and U.S. patent application Ser. No. 17/286,407 to Yuan et al., entitled “DOPED OR UNDOPED SILICON CARBIDE DEPOSITION AND REMOTE HYDROGEN PLASMA EXPOSURE FOR GAPFILL,” filed Apr. 16, 2021, each of which is incorporated by reference in its entirety and for all purposes.

In some cases, the silicon-containing film may be conformally deposited in the recessed features using ALD or PEALD. In some implementations, the silicon-containing film is conformally deposited in the recessed features using remote plasma ALD. ALD is a technique that deposits thin layers of material using sequential self-limiting reactions. Typically, an ALD cycle includes operations to deliver and adsorb at least one precursor to the substrate surface, and then react the adsorbed precursor with one or more reactants to form the partial layer of film. As an example, a silicon nitride ALD cycle may include the following operations: (i) delivery/adsorption of a silicon-containing precursor, (ii) purging of silicon-containing precursor from the chamber, (iii) exposure of nitrogen-containing reactant(s) with optional plasma, and (iv) purging of excess reactant(s) from the chamber. In some implementations, the plasma may include radical species of nitrogen, ammonia, and/or hydrogen (N*, NH₂*, NH*, and/or H*) that react with the adsorbed silicon-containing precursor to deposit silicon nitride film. In some cases, the plasma may be an in-situ plasma or remote plasma. Other types of films may be deposited using pulses of various precursors and co-reactants.

In some cases, the silicon-containing film may be conformally deposited in the recessed features using thermal CVD or thermal ALD, and subsequently performing a plasma treatment operating with a densifying gas plasma to thereby vary a composition or density of the silicon-containing film. The thermal CVD or thermal ALD operation may be performed at a substrate temperature less than about 700° C. or less than about 650° C. The plasma treatment operation may be performed at a substrate temperature less than about 700° C. or less than about 650° C. Deposition of the silicon-containing film by thermal CVD or thermal ALD may proceed using a silicon-containing precursor that is halogen-free.

The silicon-containing film is deposited to a thickness that partially fills the recessed features. The silicon-containing film is formed continuously along bottom, sidewall, and top surfaces of the recessed features. In some implementations, the thickness of the silicon-containing film is equal to or less than about 200 Å, between about 0.5 Å and about 100 Å, between about 1 Å and about 20 Å, or between about 1 Å and about 10 Å.

At block 340 of the process 300, at least a portion of the silicon-containing film is etched to at least one of a desired depth and desired profile by exposure to remote plasma. In some implementations, the remote plasma is a remote hydrogen plasma. Remote plasma exposure is provided under conditions to achieve a controlled etch of the silicon-containing film in the recessed features. In addition or in the alternative to densifying or treating the silicon-containing film, the remote plasma selectively removes a controlled amount of the silicon-containing film at or near the top of the recessed features, and selectively removes another controlled amount of the silicon-containing film along the sidewalls of the recessed features. As used herein, a “controlled etch” or “controlled amount” does not refer to exact amounts or values, but refers more broadly to a general shape of the silicon-containing film that is achieved by the remote plasma exposure. Likewise, as used herein, a “desired profile” and “desired depth” does not refer to exact amounts or values, but refers more broadly to an obtained profile that approximates to a target profile and an obtained depth that approximates to a target depth. In some instances, the desired profile or desired depth is a profile or depth that is within 1 nm of a target profile or target depth and anywhere within 5 degrees or within 10 degrees of a target taper angle. The remote plasma etch preferentially removes more of the silicon-containing film at a certain location of the recessed features than at other locations of the recessed features. How much of the silicon-containing film is removed at various locations (i.e., top, bottom, sidewalls) of the recessed features is influenced by conditions of the remote plasma etch.

In some implementations, the remote plasma includes one or more plasma-activated species comprising radicals of hydrogen (H*), halides (e.g., F*, Cl*), hydrocarbons (e.g., CH*), fluorocarbons (e.g., CF*), amines (e.g., NH*) or combinations thereof. For example, the one or more plasma-activated species include radicals of hydrogen. The plasma-activated species may be generated from one or more source gases. Example source gases may include but are not limited to hydrogen (H₂), fluorine (F₂), chlorine (Cl₂), bromine (Br₂), hydrogen fluoride (HF), hydrogen chloride (HCl), hydrogen bromide (HBr), nitrogen trifluoride (NF₃), boron trichloride (BCl₃), ammonia (NH₃), methane (CH₄), ethane (C₂H₆), acetylene (C₂H₂), ethylene (C₂H₄), propylene (C₃H₆), butene (C₄H₈), pentadiene (C₅H₈), hexene (C₆H₁₂), propyne (CH₄), butyne (C₄H₆), pentyne (C₅H₈), toluene (C₂H₈), benzene (C₆H₆), tetrafluoromethane (CF₄), octafluorocyclobutane (C₄F₈), hexafluorobutadiene (C₄F₆), and difluoromethane (CH₂F₂). The one or more source gases are delivered to a remote plasma source from a gas supply source. In some cases, the one or more source gases are supplied with an inert gas such as argon, helium, neon, krypton, or xenon. The one or more source gases are ignited to generate plasma including the plasma-activated species. The plasma-activated species may include ions, radicals, charged neutrals, and other reactive species of the one or more source gases. The plasma-activated species may be delivered from the remote plasma source to the process chamber to etch at least a portion of the silicon-containing film. In some embodiments, the remote plasma source is located upstream of the process chamber.

The remote plasma etch occurs without delivery of any silicon-containing precursors. While deposition of the silicon-containing film may involve delivery of silicon-containing precursors, remote plasma exposure for etching at least a portion of the silicon-containing film ceases any flow of silicon-containing precursors. In addition or in the alternative, the remote plasma etch occurs without delivery of any oxygen-containing species, any carbon-containing species, or any nitrogen-containing species. Though some of the aforementioned species may be used as dopants during conversion of an amorphous silicon layer to form a multi-element silicon-containing film, such species are not flowed during remote plasma etch.

In some implementations, deposition of the silicon-containing film occurs in the same process chamber as the remote plasma etch. Conformal deposition of the silicon-containing film may take place in the process chamber and etching at least a portion of the silicon-containing film using remote plasma may also take place in the process chamber. This allows deposition and etch to occur in the same tool or chamber so that deposition and etch occur without introducing a vacuum break (e.g., air break). A vacuum break can reduce throughput and cause oxidation of the substrate, which can lead to higher electrical resistance and decreased performance. In some cases, a plasma treatment operation using a densifying gas plasma and the remote plasma etch may occur in the same process chamber.

One or both of the desired profile and desired depth are achieved by modulating one or more of the following etch parameters: chamber pressure, substrate temperature, exposure time, gas composition of the remote plasma, relative concentrations of the gas composition, and RF power. One or more of the foregoing etch parameters may be controlled to produce different types of etch profiles and etch depths. Typically, conventional etches of silicon-containing films involve fluorine-based etchants that leave unwanted residue or conventional etches of silicon-containing films may be control and directionality. The remote plasma etch of the present disclosure provides various etch profiles and depths according to the conditions of the remote plasma. This allows for controlled feature top and/or sidewall silicon-containing film removal.

In some embodiments, the depth of the remote plasma etch is modulated according to chamber pressure. The chamber pressure may be between about 0.01 Torr and about 10 Torr, between about 0.05 Torr and about 5 Torr, or between about 0.1 Torr and about 2 Torr. Generally speaking, the chamber pressure can be modulated to obtain a more effective concentration of etchant. By modulating to a lower pressure, the etch rate increases and the etch depth becomes deeper. More silicon-containing film may be selectively etched at or near a top of the recessed features than at or near a middle and bottom of the recessed features with high pressures, and more silicon-containing film may be etched at or near the top and middle of the recessed features than at or near the bottom of the recessed features with lower pressures.

In some embodiments, the depth of the remote plasma etch is modulated according to RF power. The RF power may be between about 300 W and about 15 kW per station, between about 500 W and about 10 kW per station, or between about 1 kW and about 8 kW per station. The RF power can be adjusted to increase generation of hydrogen radical species, amine radical species, or other radical species. In some embodiments, the remote plasma source may be an inductively-coupled plasma (ICP) reactor for generation of radical species. By modulating to a higher RF power, the concentration of etchant increases and the etch depth becomes deeper. More silicon-containing film may be selectively etched at or near a top of the recessed features than at or near a middle and bottom of the recessed features with low RF power, and more silicon-containing film may be selectively etched at or near the top and middle of the recessed features than at or near the bottom of the recessed features with higher RF powers.

In some embodiments, the depth of the remote plasma etch is modulated according to substrate temperature. The substrate temperature may be between about 25° C. and about 750° C., between about 50° C. and about 700° C., or between about 200° C. and about 650° C. The temperature can be adjusted to increase the etch rate of the silicon-containing film. By modulating to a lower temperature, the etch depth becomes deeper. Medium temperatures may selectively remove more silicon-containing film at or near a top of the recessed features than at or near a middle and bottom of the recessed features, and lower temperatures may selectively remove more silicon-containing film at or near the top and middle of the recessed features than at or near the bottom of the recessed features.

In some embodiments, the depth of the remote plasma etch is modulated according to exposure time. The exposure time may be between about 1 second and about 5 minutes, between about 2 seconds and about 3 minutes, or between about 5 seconds and about 2 minutes. It will be understood that the exposure time may vary depending on the dimensions of the recessed features. By modulating to longer exposure times, the etch depth becomes deeper.

In some embodiments, at least one of the depth and profile of the remote plasma etch are modulated according to relative concentrations of the gas composition. The gas composition may include a source gas such as hydrogen, ammonia, one or more hydrocarbons, one or more fluorocarbons, one or more halides, or mixtures thereof. The gas composition may further include an inert gas such as argon, helium, neon, krypton, or xenon. For example, the gas composition may include a mixture of hydrogen and helium or a mixture of hydrogen and argon. The relative concentrations of hydrogen and inert gas may be modulated to influence etch depth and/or profile. In some implementations, a flow rate ratio of hydrogen to inert gas may be between about 1:10 and about 100:1, between about 1:2 and about 50:1, or between about 1:1 and about 20:1.

Whether increasing a concentration of the source gas increases or decreases an etch rate depends on the chemistry of the source gas. Accordingly, an increased concentration of the source gas may or may not result in a deeper etch. In cases with hydrogen and inert gas, modulating to a medium to low concentration of source gas results in a deeper etch depth. Low source gas concentrations may selectively remove more silicon-containing film at or near a top of the recessed features than at or near a middle and bottom of the recessed features.

Increasing or decreasing a source gas concentration relative to inert gas concentration may influence a profile of the remote plasma etch. Other etch parameters such as chamber pressure, substrate temperature, RF power, exposure time, and gas composition may additionally or alternatively influence the profile of the remote plasma etch. By controlling deposition thickness and etch depth in each step, a final film profile with a desired taper can be formed. In some cases, controlling the pressure or mean free path can serve to alter the taper of the film in the recessed feature. For example, a lower pressure may result in deeper diffusion of hydrogen radicals in the recessed feature, and a higher pressure may result in a more concentrated etch near the top of the recessed feature. Notwithstanding, a combination of pressure, temperature, plasma power, exposure time, and gas composition may tune etch profile in the present disclosure. An etch profile may be described in terms of a shape of the silicon-containing film at various locations (i.e., top, bottom, sidewalls) of the recessed features. In some cases, the etch profile may have a taper so that a thickness of the silicon-containing film diminishes closer to a top of the recessed feature than at a bottom of the recessed feature. A degree of taper may be measured by a slope or angle from an upper region of the silicon-containing film in the recessed feature against a line perpendicular to the substrate surface. The slope or angle may be between 0 degrees and 60 degrees, between about 5 degrees and about 50 degrees, or between about 10 degrees and about 45 degrees. In some cases, the etch profile may have a rounded corner or sharp corner at the upper region of the silicon-containing film in the recessed feature. In some cases, the etch profile may reflect notching, bowing, undercutting, faceting, and other deviations from a vertically-shaped film in the recessed feature.

Manipulating the various knobs of the remote plasma etch can modify the etch depth and etch profile of the remote plasma etch. In some implementations, the remote plasma etch removes more of the silicon-containing film near an opening of the recessed features than along sidewalls and at a bottom of the recessed features. In some implementations, the remote plasma etch provides a tapered etch profile. For example, the tapered etch profile may be between about 30 degrees and about 70 degrees. In some implementations, the remote plasma etch removes at least 10%, at least 20%, at least 25%, at least 30%, at least 40%, or at least 50% of the silicon-containing film from the top of the recessed features. For instance, the remote plasma etch partially removes the silicon-containing film so that between about 10% and about 50% of the silicon-containing film is removed from the top of the recessed features.

In some implementations, the process 300 further includes repeating deposition and etch operations to fill or at least substantially fill the recessed features. As used herein, substantially filled with respect to filling the recessed features can refer to having silicon-containing gapfill material occupying at least 98% of a volume of the recessed features. The recessed features may be filled without seams or voids. Controlling the shape and depth of the remote plasma etch in between deposition operations can enable gapfill without seams or voids. After the remote plasma etch at block 340, the process 300 may be followed by deposition of an additional thickness of the silicon-containing film to serve as gapfill material. The initially deposited silicon-containing film and any additional thickness of the silicon-containing film may constitute the silicon-containing gapfill material. The additional thickness of the silicon-containing film may partially fill or completely fill the one or more recessed features. Some aspects of depositing the additional thickness of the silicon-containing film may be identical to depositing and forming the silicon-containing film at block 330. Afterwards, the process 300 may be followed by another remote plasma etch that shapes the silicon-containing gapfill material according to at least one of a desired depth and desired profile. Some aspects of this remote plasma etch may be identical to the remote plasma etch at block 340. However, etch parameters such as chamber pressure, substrate temperature, RF power, gas composition, and relative concentrations of the gas composition may be the same or different than block 340. Deposition and etch operations may be repeated at least one time, at least two times, at least three times, at least five times, at least eight times, or at least ten times before a final deposition of silicon-containing gapfill material is performed to fill or at least substantially fill the recessed features.

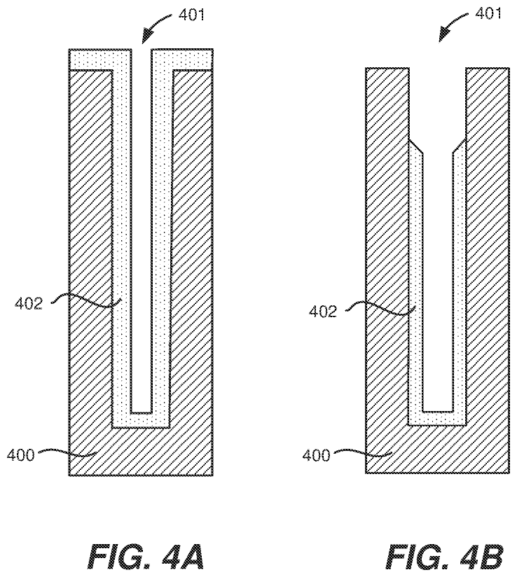

FIGS. 4A-4B show cross-sectional schematic illustrations of a feature of an example substrate being partially etched to a shallow depth using remote plasma according to some implementations. FIG. 4A shows an example of a feature 401 of a substrate 400 where a silicon-containing layer 402 is deposited in the feature 401. The silicon-containing layer 402 is conformally deposited along a top surface, sidewalls, and a bottom surface of the feature 401. In some embodiments, the silicon-containing layer 402 is an amorphous silicon layer deposited by thermal CVD using a silane-based precursor that thermally decomposes on exposed surfaces of the substrate 400. In some embodiments, the silicon-containing layer 402 is a doped silicon layer such as silicon oxide, silicon nitride, silicon carbide, silicon oxycarbide, silicon carbonitride, silicon oxynitride, or silicon oxycarbonitride. The doped silicon layer may be deposited using any suitable deposition technique such as ALD, PEALD, CVD, PECVD, or other technique. For example, the doped silicon layer may be deposited by remote plasma CVD. Alternatively, the doped silicon layer may be formed by converting the amorphous silicon layer, where conversion occurs by exposing the amorphous silicon layer to plasma flow comprising gas species containing carbon, nitrogen, and/or oxygen. Alternatively, conversion may occur by exposing the amorphous silicon layer to elevated temperatures while flowing gas species comprising carbon, nitrogen, and/or oxygen, where elevated temperatures may be between about 200° C. and about 650° C. In some implementations, the silicon-containing layer 402 is deposited by thermal CVD or thermal ALD and is followed by a plasma treatment operation using a densifying gas plasma. The plasma treatment operation can vary at least the composition of or density of the silicon-containing layer 402. The silicon-containing layer 402, which may comprise the amorphous silicon layer or the doped silicon layer, may be deposited with a step coverage of at least 85%, at least 90%, or at least 95% in the feature 401. The silicon-containing layer 402 only partially fills the feature 401.

FIG. 4B shows an example of the feature 401 of the substrate 400 where the silicon-containing layer 402 is partially etched. The substrate 400 may be exposed to remote plasma under conditions to partially etch the silicon-containing layer 402 to a shallow depth. The remote plasma may remove the silicon-containing layer 402 to an etch depth that reaches between about 1% and 50% of the depth from the top of the feature 401, between about 5% and about 45% of the depth from the top of the feature 401, or between about 10% and about 40% of the depth from the top of the feature 401. In some implementations, the partially etched silicon-containing layer 402 may have a tapered profile. The remote plasma removes the silicon-containing layer 402 from the top of the feature 401 instead of the middle or bottom of the feature 401. The remote plasma may comprise one or more gas species including hydrogen, ammonia, one or more hydrocarbons, one or more fluorocarbons, one or more halides, or mixtures thereof. In some embodiments, the remote plasma comprises hydrogen and an inert gas. In some embodiments, the remote plasma may be generated in a plasma source located upstream of a process chamber for depositing and etching the silicon-containing layer 402. The remote plasma controls etch parameters of chamber pressure, substrate temperature, RF power, exposure time, gas composition, and/or relative concentrations of the gas composition to conduct the partial etch shown in FIG. 4B. By tuning one or more of the foregoing etch parameters, the silicon-containing layer 402 may undergo a partial etch to the desired depth and/or profile in the feature 401. In some implementations, the remote plasma for removing at least a portion of the silicon-containing layer 402 may proceed after a plasma treatment operation on the silicon-containing layer 402 using a densifying gas plasma.

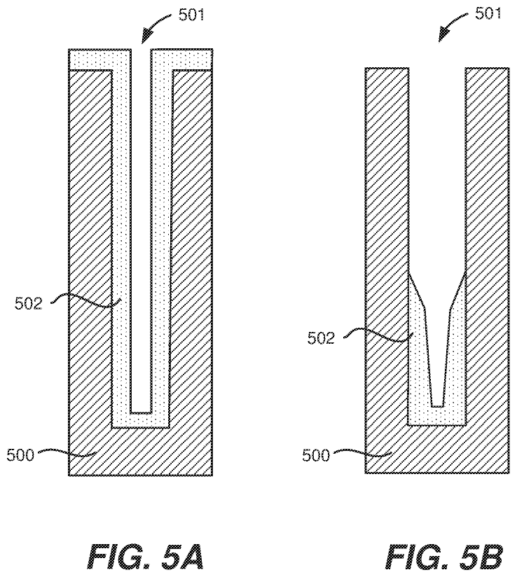

FIGS. 5A-5B show cross-sectional schematic illustrations of a feature of an example substrate being partially etched to a deep depth using remote plasma according to some implementations. FIG. 5A shows an example of a feature 501 of a substrate 500 where a silicon-containing layer 502 is deposited in the feature 501. The silicon-containing layer 502 is conformally deposited along a top surface, sidewalls, and a bottom surface of the feature 501. In some embodiments, the silicon-containing layer 502 is an amorphous silicon layer deposited by thermal CVD using a silane-based precursor that thermally decomposes on exposed surfaces of the substrate 500. In some embodiments, the silicon-containing layer 502 is a doped silicon layer such as silicon oxide, silicon nitride, silicon carbide, silicon oxycarbide, silicon carbonitride, silicon oxynitride, or silicon oxycarbonitride. The doped silicon layer may be deposited using any suitable deposition technique such as ALD, PEALD, CVD, PECVD, or other technique. For example, the doped silicon layer may be deposited by remote plasma CVD. Alternatively, the doped silicon layer may be formed by converting the amorphous silicon layer, where conversion occurs by exposing the amorphous silicon layer to plasma flow comprising gas species containing carbon, nitrogen, and/or oxygen or by exposing the amorphous silicon layer to elevated temperatures while flowing gas species containing carbon, nitrogen, and/or oxygen to the substrate. In some implementations, the doped silicon layer may be formed by thermal CVD or thermal ALD, followed by a plasma treatment operation using a densifying gas plasma. The silicon-containing layer 502, which may comprise the amorphous silicon layer or the doped silicon layer, may be deposited with a step coverage of at least 85%, at least 90%, or at least 95% in the feature 401. The silicon-containing layer 502 only partially fills the feature 501.

FIG. 5B shows an example of the feature 501 of the substrate 500 where the silicon-containing layer 502 is partially etched. The substrate 500 may be exposed to remote plasma under conditions to partially etch the silicon-containing layer 502 to a deep depth. The remote plasma may remove the silicon-containing layer 502 to an etch depth that reaches between about 40% and 95% of the depth from the top of the feature 501, between about 50% and about 90% of the depth from the top of the feature 501, or between about 60% and about 85% of the depth from the top of the feature 501. In some implementations, the partially etched silicon-containing layer 502 may have a tapered profile. The silicon-containing layer 502 of FIG. 5B may be etched to a different depth and profile than the silicon-containing layer 402 of FIG. 4B. The remote plasma removes more of the silicon-containing layer 502 from the top of the feature 501 than from the bottom of the feature 501. The remote plasma may comprise one or more gas species including hydrogen, ammonia, one or more hydrocarbons, one or more fluorocarbons, one or more halides, or mixtures thereof. In some embodiments, the remote plasma comprises hydrogen and an inert gas. In some embodiments, the remote plasma may be generated in a plasma source located upstream of a process chamber for depositing and etching the silicon-containing layer 502. The remote plasma controls etch parameters of chamber pressure, substrate temperature, RF power, exposure time, gas composition, and/or relative concentrations of the gas composition to conduct the partial etch shown in FIG. 5B. By tuning one or more of the foregoing etch parameters, the silicon-containing layer 502 may undergo a partial etch to the desired depth and/or profile in the feature 501.

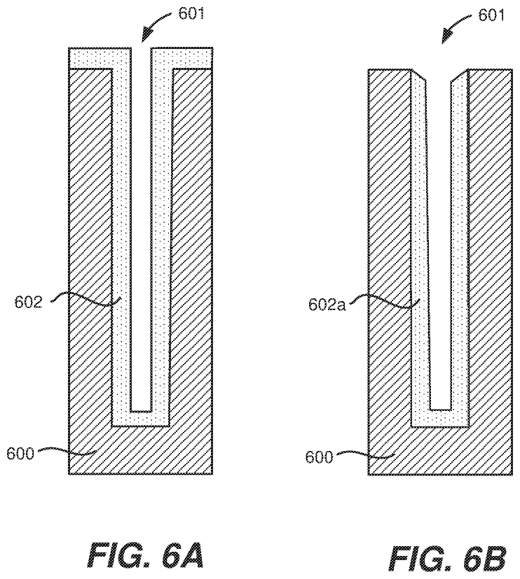

FIGS. 6A-6B show cross-sectional schematic illustrations of a feature of an example substrate being partially etched at a top surface using remote plasma according to some implementations. FIG. 6A shows an example of a feature 601 of a substrate 600 where a silicon-containing layer 602 is deposited in the feature 601. The silicon-containing layer 602 is conformally deposited along a top surface, sidewalls, and a bottom surface of the feature 601. In some embodiments, the silicon-containing layer 602 is an amorphous silicon layer deposited by thermal CVD using a silane-based precursor that thermally decomposes on exposed surfaces of the substrate 600. In some embodiments, the silicon-containing layer 602 is a doped silicon layer such as silicon oxide, silicon nitride, silicon carbide, silicon oxycarbide, silicon carbonitride, silicon oxynitride, or silicon oxycarbonitride. The doped silicon layer may be deposited using any suitable deposition technique such as ALD, PEALD, CVD, PECVD, or other technique. For example, the doped silicon layer may be deposited by remote plasma CVD. Alternatively, the doped silicon layer may be formed by converting the amorphous silicon layer, where conversion occurs by exposing the amorphous silicon layer to plasma flow comprising gas species containing carbon, nitrogen, and/or oxygen or by exposing the amorphous silicon layer to elevated temperatures while flowing gas species containing carbon, nitrogen, and/or oxygen to the substrate. In some implementations, the doped silicon layer may be formed by thermal CVD or thermal ALD, followed by a plasma treatment operation using a densifying gas plasma. The silicon-containing layer 602, which may comprise the amorphous silicon layer or the doped silicon layer, may be deposited with a step coverage of at least 85%, at least 90%, or at least 95% in the feature 601. The silicon-containing layer 602 only partially fills the feature 601.

FIG. 6B shows an example of the feature 601 of the substrate 600 where the silicon-containing layer 602 is partially etched. The substrate 600 may be exposed to remote plasma under conditions to partially etch the silicon-containing layer 602 so that the silicon-containing layer 602 is substantially removed from the top surface of the feature 601 while the silicon-containing layer 602 along sidewalls and the bottom surface of the feature 601 is substantially preserved. The silicon-containing layer 602 may be shaped so that an opening at the top surface of the feature 601 is larger than an opening at the middle or bottom of the feature 601. The opening at the top surface of the feature 601 may be tapered as the silicon-containing layer 602 extends downwards. The silicon-containing layer 602 of FIG. 6B may be etched to a different depth and profile than the silicon-containing layer 502 of FIG. 5B and etched to a different depth and profile than the silicon-containing layer 402 of FIG. 4B. The remote plasma may comprise one or more gas species including hydrogen, ammonia, one or more hydrocarbons, one or more fluorocarbons, one or more halides, or mixtures thereof. In some embodiments, the remote plasma comprises hydrogen and an inert gas. In some embodiments, the remote plasma may be generated in a plasma source located upstream of a process chamber for depositing and etching the silicon-containing layer 602. The remote plasma controls etch parameters of chamber pressure, substrate temperature, RF power, exposure time, gas composition, and/or relative concentrations of the gas composition to conduct the partial etch shown in FIG. 6B. By tuning one or more of the foregoing etch parameters, the silicon-containing layer 602 may undergo a partial etch to the desired depth and/or profile in the feature 601.

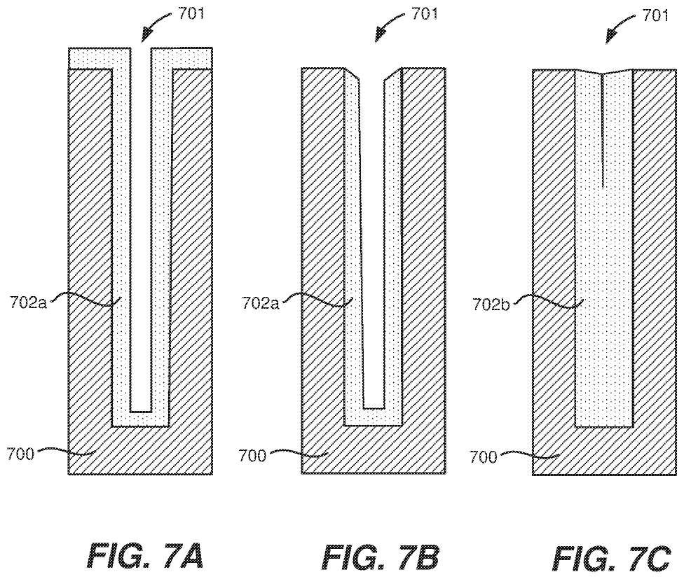

FIGS. 7A-7C show cross-sectional schematic illustrations of a feature of an example substrate undergoing gapfill in a dep-etch-dep process according to some implementations. The operations of gapfill may include additional, fewer, or different operations than shown in FIGS. 7A-7C. The operations of gapfill may be performed using a plasma processing apparatus as shown in FIGS. 12 and 13.

At FIG. 7A, a first thickness of a silicon-containing layer 702a is deposited in a feature 701 of a substrate 700. Though the substrate 700 shows only a single feature 701, it will be understood that the substrate 700 may have one or more features 701. In some embodiments, the silicon-containing layer 702a includes amorphous silicon. In some other embodiments, the silicon-containing layer 702a includes a doped silicon layer such as silicon oxide, silicon nitride, silicon carbide, silicon oxycarbide, silicon oxynitride, silicon carbonitride, or silicon oxycarbonitride. The first thickness of the silicon-containing layer 702a may be deposited using any suitable deposition technique. In cases where the silicon-containing layer 702a is amorphous silicon, for example, the silicon-containing layer 702a may be deposited by thermal CVD using a silane-based precursor that thermally decomposes at elevated temperatures to adsorb on the substrate surface. In cases where the silicon-containing layer 702a is a doped silicon layer, the silicon-containing layer 702a may be deposited by ALD, PEALD, CVD, PECVD, or other technique. Alternatively, the silicon-containing layer 702a may be formed by converting amorphous silicon, where the conversion occurs by exposure to plasma flow containing carbon, nitrogen, and/or oxygen to form doped silicon, or by exposure to elevated temperatures while flowing gas species containing carbon, nitrogen, and/or oxygen to the substrate to form doped silicon. In some implementations, the silicon-containing layer 702a may be formed by thermal CVD or thermal ALD, where the silicon-containing layer 702a is exposed to a plasma treatment operation using a densifying gas plasma that affects the composition and/or density of the silicon-containing layer 702a. The silicon-containing layer 702a, which may comprise the amorphous silicon layer or the doped silicon layer, may be deposited with a step coverage of at least 85%, at least 90%, or at least 95% in the feature 701.

At FIG. 7B, the first thickness of the silicon-containing layer 702a is exposed to remote plasma to partially etch the silicon-containing layer 702a. The etch is performed under conditions that increase a size of an opening at the top surface of the feature 701. The remote plasma may etch the silicon-containing layer 702a to a shallow depth so that the opening is free of gapfill material near the top of the feature 701. The remote plasma may etch the silicon-containing layer 702a to a tapered profile that narrows as the silicon-containing layer 702a extends downwards in the feature 701. The remote plasma may comprise one or more gas species including hydrogen, ammonia, one or more hydrocarbons, one or more fluorocarbons, one or more halides, or mixtures thereof. In some implementations, the remote plasma comprises hydrogen and an inert gas. In some implementations, the remote plasma may be generated in a plasma source located upstream of a process chamber for depositing and etching the silicon-containing layer 702a. This allows alternating deposition and remote plasma etch cycles to be performed in the same tool or chamber. As a result, deposition and etch may occur without introducing a vacuum break (e.g., air break) during gapfill. The remote plasma controls etch parameters of chamber pressure, substrate temperature, RF power, exposure time, gas composition, and/or relative concentrations of the gas composition to conduct the partial etch shown in FIG. 7B. By tuning one or more of the aforementioned etch parameters, the silicon-containing layer 702a may undergo a partial etch to the desired depth and/or profile in the feature 701 for gapfill processes.

At FIG. 7C, a second thickness of the silicon-containing layer 702b is deposited in the feature 701 of the substrate 700. The second thickness of the silicon-containing layer 702b is deposited on the first thickness of the silicon-containing layer 702a. Some aspects of depositing the second thickness can be identical or at least similar to aspects of depositing the first thickness. The second thickness of the silicon-containing layer 702b may be the same compositionally as the first thickness of the silicon-containing layer 702a, where the silicon-containing layer 702a, 702b serve as gapfill material. Deposition of the first thickness, etch, and deposition of the second thickness may occur in the same tool or same process chamber. Deposition of the first thickness may be a thermal CVD process, etch of the first thickness may be a remote plasma etch, and deposition of the second thickness may also be a thermal CVD process, all of which may be performed in the same tool or same process chamber. Deposition of the first thickness may be a thermal CVD or thermal ALD process, treatment may be a plasma process, etch of the first thickness may be a remote plasma etch, deposition of the second thickness may also be a thermal CVD or thermal ALD process, and treatment may be a plasma process, all of which may be performed in the same tool or same process chamber. The second thickness may have a step coverage of at least 85%, at least 90%, or at least 95%. In some cases, the silicon-containing layer 702a, 702b may fill or at least substantially fill the feature 701. Interrupting deposition operations with remote plasma etch as described in the present disclosure may avoid seams and/or voids or at least minimize the sizes of seams and/or voids during gapfill. Deposition of gapfill material and remote plasma etch operations of the present disclosure may be repeated until gapfill is complete at FIG. 7C.

As discussed above, aspects of the present disclosure may relate to deposition of a silicon-containing layer in a feature followed by a controlled etch process using a remote plasma. However, irrespective of whether the silicon-containing layer deposited in the feature is followed by an etch process, aspects of the present disclosure may relate to deposition of the silicon-containing layer by thermal ALD and/or thermal CVD. Such deposition may occur using a halogen-free deposition precursor. The silicon-containing layer may have a tunable film composition and deposition. In some implementations, the silicon-containing layer deposited by thermal ALD and/or thermal CVD is treated by exposure to a densifying gas plasma. Deposition of the silicon-containing layer may be performed at temperatures less than about 700° C., such as less than about 650° C., between about 250° C. and about 350° C., such as about 275° C.

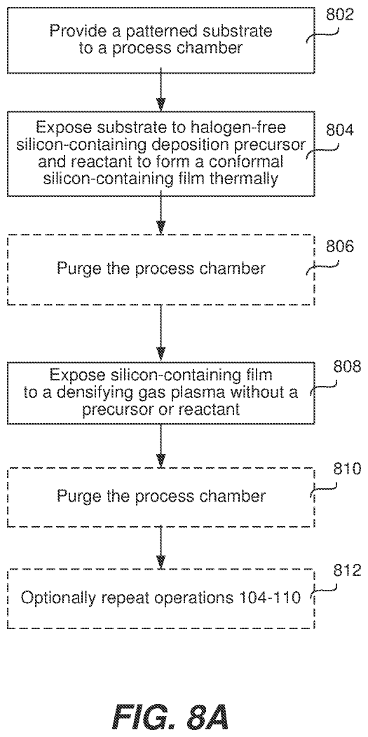

FIG. 8A provides a process flow diagram depicting operations that may be performed in accordance with certain disclosed embodiments. In operation 802, a patterned substrate may be provided in a process chamber which may be set to a chamber pressure of about 0 Torr to about 30 Torr. The pressure may vary from operation to operation or may remain the same throughout all operations in FIG. 8A or may be the same in two or more operations in FIG. 8A. Example process chambers are further described below with respect to FIGS. 12 and 13. As described above, the substrate may be a silicon wafer having one or more dielectric, conducting, or semiconducting material deposited thereon. The substrate may be patterned with features having an aspect ratio between about 1:1 and about 60:1, or greater than about 1.5:1, or greater than about 4:1, or between about 1.5:1 and 60:1, or between about 1.5:1 and 40:1, or between about 1.5:1 and 20:1, such as about 5:1. When a patterned substrate is provided to a process chamber, the substrate may be subject to a “temperature soak” whereby the substrate is heated to the process temperature upon which the substrate will be subject to operations described herein. For example, in some embodiments, the substrate may be heated to a temperature less than about 700° C., such as less than about 650° C., between about 650° C. and about 400° C., or about 275° C.

In operation 804, the substrate is exposed to a silicon-containing deposition precursor and reactant to form a conformal silicon-containing film thermally. In various embodiments, “halogen-free” means the silicon-containing precursor molecule does not include any halogen substituents. In various embodiments, the silicon-containing precursor is halogen-free. The silicon-containing deposition precursor may be any suitable silicon-containing precursor, such as those listed in the Definitions and Precursors section herein. In some embodiments, the halogen-free silicon-containing precursor has a decomposition temperature of less than about 700° C., or less than about 650° C. In some embodiments, the halogen-free silicon-containing deposition precursor is an aminosilane, or an alkylsilane, or a silazane. In some embodiments, the silicon-containing precursor is trimethylsilane. In some embodiments, the silicon-containing precursor is dimethylsilane. In some embodiments, the silicon-containing precursor is tetramethylsilane.

The deposition reactant selected depends on the film to be deposited. In various embodiments, the reactant may be an oxygen-containing gas, a carbon-containing gas, and/or a nitrogen-containing gas. Example oxygen-containing gases include oxygen (O₂), ozone (O₃), peroxides such as hydrogen peroxide (H₂O₂), carbon monoxide (CO), carbon dioxide (CO₂), nitrous oxide (N₂O), nitric oxide (NO₂), and combinations thereof. Oxygen-containing reactants may help facilitate increase of oxygen content in the deposited film. Example carbon-containing gases include CO, CO₂, and combinations thereof. Carbon-containing reactants may help facilitate increase of carbon content in the deposited film. Example nitrogen-containing gases include nitrogen (N₂), ammonia (NH₃), nitrous oxide (N₂O), nitric oxide (NO₂), hydrazines such as hydrazine (N₂H₄), and combinations thereof. Nitrogen-containing reactants may help facilitate increase of nitrogen content in the deposited film.

Operation 804 may be performed by thermal CVD in some embodiments. In thermal CVD embodiments, both the deposition precursor and reactant may be flowed continuously to the process chamber housing the substrate.

Operation 804 may be performed by thermal ALD in some embodiments. In thermal ALD embodiments, the deposition precursor and reactant flows may be temporally separated; that is, when the deposition precursor is flowed, the reactant is not flowed, and when the reactant is flowed, the deposition precursor is not flowed. Each exposure of the deposition precursor and the reactant may be referred to as a “pulse.” In some embodiments, the “pulse” of the deposition precursor may be referred to as a “dose.” The “pulse” of the reactant may be referred to as “conversion,” which may refer to the converting of adsorbed precursor molecules to the film material. However it will be understood that while “conversion” assumes the precursor has already been adsorbed, in some embodiments, the pulse of the reactant may be performed even if the deposition precursor has not yet been pulsed or the substrate does not have adsorbed deposition precursor molecules. The temporally separated pulses may be pulsed in cycles, such that each cycle includes one pulse of deposition precursor and one pulse of reactant.

FIG. 8B shows an example process flow diagram of operations that may be performed in thermal ALD as a deposition technique for performing operation 804 in FIG. 8A. In operation 804-a, the substrate is exposed to the halogen-free silicon-containing deposition precursor which may adsorb onto the substrate surface. In some embodiments, adsorption on the surface of the substrate may be form a thin layer of the silicon-containing precursor on the surface of the substrate. The thin layer may be less than a monolayer, and may have a thickness between about 0.5 Å and about 2.0 Å. During operation 804-a, a carrier gas may be flowed. A carrier gas may be used to co-flow with the silicon-containing precursor in some embodiments. The carrier gas may be an inert gas, such as helium, argon, neon, and combinations thereof. The carrier gas may be diverted such that the carrier gas is used to deliver the deposition precursor gas to the process chamber. In some embodiments, the carrier gas may be provided to assist with pressure and/or temperature control of the process chamber. In some embodiments, the carrier gas is used to ensure more rapid delivery of a gas to the process chamber. The carrier gas may be provided to assist with pressure and/or temperature control of the process chamber, evaporation of a liquid reactant, more rapid delivery of the reactant and/or as a sweep gas for removing process gases from the process chamber and/or process chamber plumbing.

In operation 804-b, the process chamber is optionally purged. Prior to purging, the flow of the halogen-free silicon-containing precursor may be stopped or diverted from the process chamber. Purging may remove silicon-containing precursors that did not adsorb onto the substrate surface. Purging the chamber may involve flowing a purge gas or a sweep gas, which may be a carrier gas used in other operations or may be a different gas. In some embodiments, purging may involve evacuating the chamber. Example purge gases include argon, nitrogen, hydrogen, and helium. In some embodiments, operation 804-b may include one or more evacuation subphases for evacuating the process chamber. Alternatively, it will be appreciated that operation 804-b may be omitted in some embodiments. Operation 804-b may have any suitable duration, such as between about 0 seconds and about 60 seconds, for example about 0.01 seconds. In some embodiments, increasing a flow rate of one or more purge gases may decrease the duration of operation 804-b. For example, a purge gas flow rate may be adjusted according to various reactant thermodynamic characteristics and/or geometric characteristics of the process chamber and/or process chamber plumbing for modifying the duration of operation 804-b. In one non-limiting example, the duration of a purge phase may be adjusted by modulating purge gas flow rate. This may reduce deposition cycle time, which may improve substrate throughput. After a purge, the silicon-containing precursor molecules remain adsorbed onto the substrate surface. In some embodiments, the purge gas is flowed to a chamber housing the substrate at a flow rate between about 100 sccm and about 5000 sccm.

In operation 804-c, the substrate is exposed to a reactant without a plasma to form a silicon-containing film on the substrate surface. In some embodiments, this operation allows the reactant to react with adsorbed silicon-containing precursor molecules to convert the silicon-containing precursor molecules to molecules of the silicon-containing film. It will be understood that while this example in FIG. 8B involves adsorption prior to exposure to the reactant, in some embodiments, the substrate may be exposed to the reactant and then exposed to the silicon-containing precursor. Operation 804-c is performed without a plasma such that the reaction between the silicon-containing precursor and the reactant is a thermal reaction.

In some embodiments, the reactant, as described above, may be an oxygen-containing reactant, or an oxidizing agent. In some embodiments, the silicon-containing precursor is an aminosilane and the reactant is an oxidizing agent; in such cases, the reaction between the aminosilane and the oxidizing agent is a thermal reaction such that plasma is not necessary to drive the reaction. In some embodiments, the reactant is flowed into a chamber housing the substrate at a flow rate between about 1 sccm and about 5000 sccm.

In operation 804-d, the chamber is optionally purged to remove any residual byproducts. Operation 804-d may be performed using any of the conditions described above with respect to operation 804-b.

It is determined whether the desired thickness of film has been deposited. If not, operations 804-a to 804-d are repeated in sufficient cycles to deposit a desired thickness of silicon-containing film. Any suitable number of deposition cycles may be included in an ALD process to deposit a desired film thickness of a silicon-containing film. For example, about fifty deposition cycles may be performed to deposit a silicon-containing film on the substrate using disclosed embodiments. In some embodiments, the silicon-containing film is formed to a thickness of about 1 Å to about 30 Å.

Returning to FIG. 8A, in operation 806, the process chamber may be optionally purged. Operation 806 may be performed using any of the conditions described above with respect to operation 804-b of FIG. 8B. Purging may be used to eliminate deposition precursors and/or reactants from the chamber and/or from a processing region over the substrate surface.

In operation 808, after at least a portion of the silicon-containing film is deposited, the silicon-containing film is exposed to a densifying plasma either (1) without a precursor or a reactant or (2) with a densifying gas. For example, the densifying plasma may be generated by igniting a densification gas, which may include but is not limited to hydrogen (H₂) gas, oxygen-containing gas, nitrogen-containing gas, and combinations thereof. Gases may be selected depending on the type of film to be deposited and the reactants used during the deposition process. A general list of possible gases includes nitrogen only, ammonia only, nitrogen/ammonia mixture, argon only, helium only, argon/helium mixture, oxygen only, oxygen/nitrogen mixture, hydrogen/oxygen mixture, hydrogen only, hydrogen/nitrogen mixture, and combinations thereof. Other noble gases may also be used.

Exposure to the densifying plasma may vary at least the composition of or the density of the portion of the silicon-containing film. The composition of the silicon-containing film refers to the relative amounts of silicon as well as oxygen, carbon, nitrogen, and hydrogen.

In some embodiments, even if nitrogen is used in operation 808 to form silicon nitride, operation 808 may involve exposure to nitrogen plasma during post-treatment to reduce hydrogen content and densify the film.

In various embodiments, an oxygen-free plasma is used; that is, oxygen (O₂) gas or an oxygen-containing gas is not used to generate plasma.

Operation 808 is performed for a particular duration sufficient to densify or treat the silicon-containing film. In some embodiments, operation 808 is performed for a duration of about 10 seconds to about 60 seconds.

The plasma may be ignited at a plasma frequency of 13.56 MHz. In some embodiments, the plasma is generated using a dual frequency radio frequency generator. In some embodiments, the plasma power is about 0 to about 6500 W per station during operation 808 or about 100 W to about 6500 W. In some embodiments, the plasma is generated using a single frequency radio frequency generator. In various embodiments, the plasma power for a high frequency plasma is about 400 W (0.1 W/cm²) to about 5000 W (1.5 W/cm²). In various embodiments, the plasma power for a low-frequency plasma is about 400 W (0.1 W/cm²) to about 3000 W (1 W/cm²). In some embodiments, exposure to the plasma is performed in pulses. For example, instead of turning on the plasma and keeping it on during operation 808, in some embodiments, operation 808 involves pulsing the plasma between an on and off phase or between a high and low phase. The plasma may be pulsed at a pulse frequency of about 2 Hz to about 100 kHz with duty cycle ranging from about 1% to about 95%. The duty cycle is defined as the duration for which the plasma is on during a period having a duration T. The duration T includes the duration for pulse ON time (the duration for which the plasma is in an ON state) and the duration for plasma OFF time (the duration from which the plasma is in an OFF state) during a given period. The pulse frequency will be understood as 1/T. For example, for a plasma pulsing period T=100 μs, frequency is 1/T=1/100 μs, or 10 kHz. The duty cycle or duty ratio is the fraction or percentage in a period T during which the plasma is in the ON state such that duty cycle or duty ratio is pulse ON time divided by T. For example, for a plasma pulsing period T=100 μs, if a pulse ON time is 70 μs (such that the duration for which the plasma is in an ON state in a period is 70 μs) and a pulse OFF time is 30 μs (such that the duration for which the plasma is in an OFF state in a period is 30 μs), the duty cycle is 70%. In some embodiments, the shortest RF on time during the pulse step can be as low as about 5 μsec. In some embodiments, the shortest RF off time can be about 5 μsec. Depending on the duty cycle and the frequency, various combinations of RF on/RF off pulses can be performed. For example, in some embodiments, this operation may be performed for a duration of about 0.01 ms to about 60 seconds, or about 1 second to about 60 seconds, or about 0.01 ms to about 5 ms, or about 0.02 ms to about 5 ms, or about 0.05 ms to about 5 ms, or about 0.05 ms to about 1.9 ms, or about 0.5 ms to about 1.9 ms. During operation 808, the plasma may be pulsed hundreds to thousands of time depending on total plasma duration time.

During operation 808, silicon-containing precursor and reactant are not flowed.

The plasma may be generated in situ, or within the chamber. In some embodiments, the plasma may be generated in a remote plasma generator to form plasma species that are then delivered to the process chamber via a showerhead. The plasma may be an inductively coupled plasma, or a capacitively coupled plasma, or a microwave plasma.

A densifying gas or a combination of densifying gases is flowed to the process chamber during operation 808 when the plasma is ignited, thereby generating a plasma species that may be capable of modifying and densifying the deposited film.

Operation 808 may be performed using the same substrate temperature as during operation 804. In some embodiments, operations 808 and 804 may be performed without breaking vacuum. In some embodiments, operations 808 and 804 are performed in the same chamber.

In some embodiments, operations 808 and 804 are performed at different temperatures. In some embodiments, operations 808 and 804 are performed with an air break between them, or in separate chambers.

The process conditions for densification may depend on the chemistries used to deposit the silicon-containing film, the thickness of the silicon-containing film, the topography of the substrate, the composition of layers under the silicon-containing film, and other factors.

In operation 812, operations 804-810 may be optionally repeated in numerous cycles. In some embodiments, operation 808 is performed for every about 1 Å to about 30 Å, or about 1 Å to about 20 Å of film deposition thickness of operation 804. That is, after depositing at least about 1 Å to about 30 Å, or about 1 Å to about 20 Å of the silicon-containing film in operation 804, operation 808 is performed.

Chemistry selection, process conditions, and reaction mechanism(s) used during the deposition in operation 804 and the densification in operation 808 tunes the composition and properties of the silicon-containing film. For example, in some embodiments, using a silicon-containing precursor having more Si—C bonds may result in more Si—C bonds in the resultant film. In some embodiments, when using certain silicon-containing precursors, lower temperature may be used to thereby form a film using a lower deposition rate which may affect the quality of the film. In some embodiments, toggling the gas flows and/or plasma conditions may incorporate more or less oxygen atoms or more or less hydrogen atoms. In some embodiments, multiple gases are used during deposition as additive gases. For example, multiple gases may be used during the reactant exposure in an ALD process or during deposition of the silicon-containing film by CVD which can toggle the film composition by incorporating more or certain molecules.

In some embodiments, a gradient film composition may be desired. Gradient films may be achieved by varying gas composition during deposition and/or during treatment and/or during different deposition cycles. A gradient film composition is defined as a film having a composition that varies across different regions of the film, such as by depth of the film, or across a substrate surface, or otherwise. In one limiting example, a gradient film composition may include a film having SiCON and SiCO, deposited using at least about 20 cycles of deposition alternating between depositing at least about 1 Å to about 5 Å of SiCO with little to no nitrogen content, and about 20% carbon content, and at least about 1 Å to about 5 Å of SiCON with nitrogen content of about 15% but only about 5% carbon content.

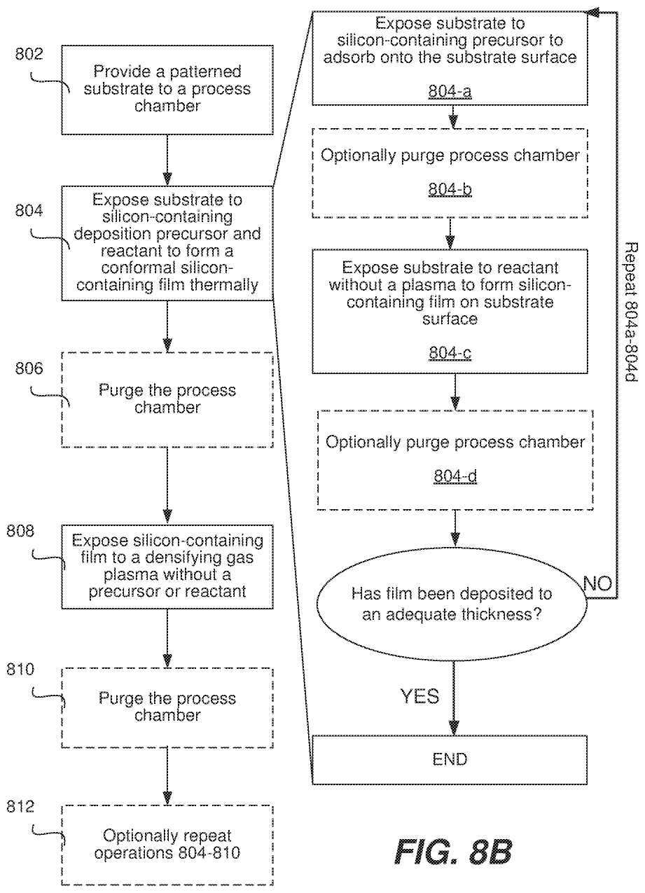

FIG. 9 is a timing sequence diagram of example pulses in accordance with disclosed embodiments. FIG. 9 shows phases in an example process 900, for various process parameters, such as reactant gas flow, densifying gas flow, silicon-containing precursor flow, and plasma status. The lines indicate when the flow is turned on and off and when the plasma is turned on and off. While the example shows on/off flow and on/off plasma status, it will be understood that in some embodiments, the flow and/or plasma may be toggled between a low and high position, as opposed to an off and on position. It will also be understood that “off” may not refer to completely turning off the valve but could also include embodiments where the gas is diverted. Various disclosed embodiments depend on process parameters that include, but are not limited to, flow rates for densifying, and reactant species, flow rates for the silicon-containing precursor gas, plasma conditions during treatment, substrate temperature, and process chamber pressure. The example in FIG. 9 refers to a CVD-based process where the silicon-containing film is deposited thermally by CVD followed by plasma treatment.

Process 900 includes two cycles—one cycle includes deposition phase 902A and periodic plasma post-treatment phase 915A. Another cycle includes deposition phase 902B and periodic plasma post-treatment phase 915B. During deposition phase 902A, densifying gas (which may be H₂) flow is off, silicon-containing precursor gas flow is turned on, reactant flow is turned on, and plasma is off. This may refer to one example of an embodiment of operation 804 of FIG. 8A. During periodic plasma post-treatment phase 915A, densifying gas flow is turned on, silicon-containing precursor flow is turned off, reactant flow is turned off, and plasma is turned on. This may refer to one example of an embodiment of operation 808 of FIG. 8A. The cycle is then repeated. In deposition phase 902B, silicon-containing precursor gas flow is turned on, reactant gas flow is turned on, and plasma is turned off while densifying gas flow is turned off. In periodic plasma post-treatment phase 915B, densifying gas flow is turned on, silicon-containing precursor gas flow is turned off, reactant flow is turned off, and plasma is turned on. This may be repeated for multiple cycles. While not indicated in FIG. 9, in some embodiments, the plasma post-treatment phase may involve flowing an oxygen-containing gas, such as oxygen, or a nitrogen-containing gas, such as nitrogen, or a mixture of both, such as a mixture of oxygen gas and nitrogen gas, in addition to or in lieu of the hydrogen densifying gas flow depicted in FIG. 9. While the densifying gas(es) are flowed, plasma may be ignited.

Certain disclosed embodiments may utilize densification to achieve particular film density. For example, for a film having density of at least about 2.0 g/cm³ to about 2.6 g/cm³, or about 2.3 g/cc, the film may be densified using plasma power of at least about 100 W to about 6500 W for about 1 second to about 60 seconds.

A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates, and can be scaled as appropriate for substrates or chambers of other sizes.

### EXPERIMENTAL

### Experiment 1:

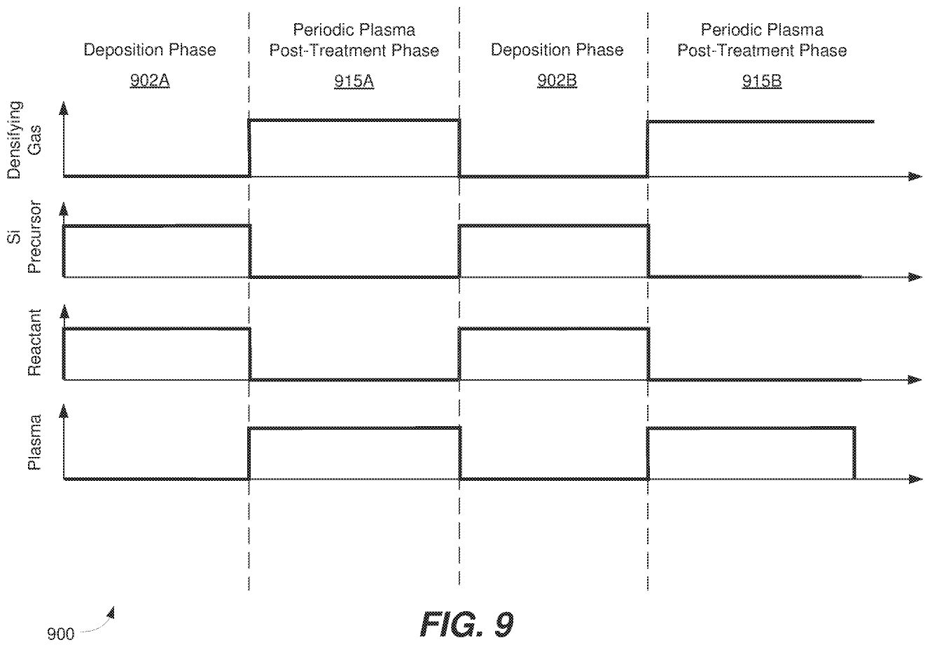

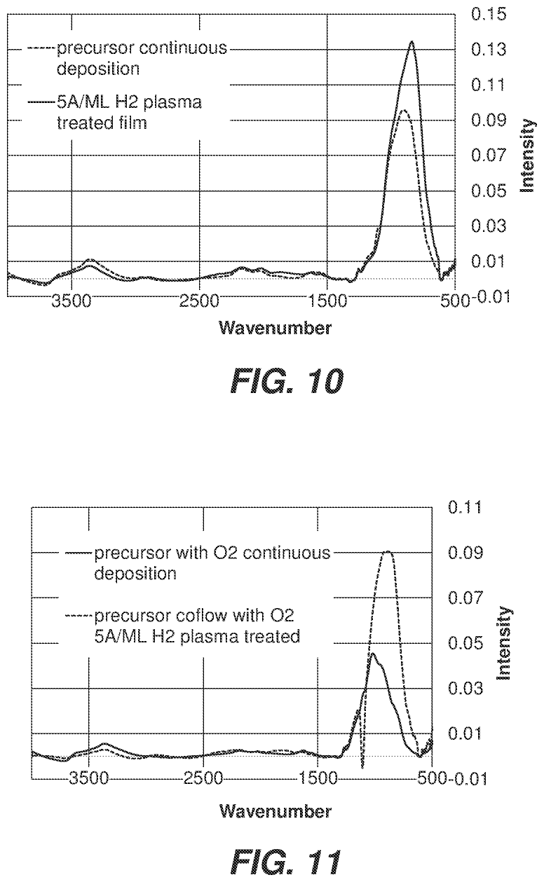

Silicon carboxynitride films were deposited using a silicon-containing precursor, with and without treating the film. With one particular precursor, The FTIR spectra for these two films are shown in FIG. 10. Silicon carboxynitride films were deposited using BTBAS and co-flowing oxygen gas, with and without treating the film. The FTIR spectra for these two films are shown in FIG. 11. These results suggest with H₂ plasma treatment, the film was densified. A typical Si—O—Si stretching peak is at 1040 cm⁻¹), Si—O bending peak at (820 cm⁻¹), SiN peak is around 840 cm⁻¹, and Si—C peak is at 810 cm⁻¹. The peak for Si—C and peaks for Si—O and Si—N are overlapped here, forming one main broad peak between 600 cm⁻¹ to 1200 cm⁻¹. The more densified the film is, the more intense main peak is; for example, the N—H peak (3350 cm⁻¹) did reduce after densification.

### Experiment 2;

Silicon carboxynitride films were deposited using the silicon-containing precursor, with and without co-flowing oxygen, and with and without treating the film. The silicon, carbon, oxygen, and nitrogen content and density in g/cc are shown in Table 1 below. These results suggest that the gas chemistry used with the precursor and the use of the treatment can affect the film composition and density. For example, the plasma treatment can be used to substantially densify the film.

TABLE 1
Silicon, Carbon, Oxygen, and Nitrogen Content & Film Density

| | | | | | Density |
|---|---|---|---|---|---|
| Condition | Si % | C % | O % | N % | (g/cc) |
| Precursor only deposition with | 33.4 | 32.7 | 12.5 | 21.4 | 1.91 |
| no plasma treatment | | | | | |
| Precursor only deposition with | 40.8 | 20.1 | 7.3 | 31.8 | 2.36 |
| plasma treatment | | | | | |
| Precursor with O₂ deposition, | 31.6 | 16.3 | 41.5 | 10.6 | 1.86 |
| no plasma treatment | | | | | |
| Precursor with O2 deposition | 37.8 | 8.0 | 33.5 | 20.7 | 2.43 |
| with plasma treatment | | | | | |

### Apparatus

One aspect of the present disclosure is an apparatus configured to accomplish the methods described herein. In some implementations, the apparatus is configured to accomplish the film deposition methods described herein. In some implementations, the apparatus is configured to accomplish film deposition methods and etch methods described herein. A suitable apparatus includes hardware for accomplishing the process operations and a system controller having instructions for controlling process operations in accordance with the present disclosure. In some embodiments, the apparatus for performing the aforementioned process operations can include a remote plasma source. A remote plasma source may provide mild reaction conditions compared to a direct plasma. An example of a suitable remote plasma apparatus is described in U.S. patent application Ser. No. 14/062,648, filed Oct. 24, 2013, which is incorporated herein by reference in its entirety and for all purposes. In some embodiments, the apparatus for performing the aforementioned process operations can include a pedestal for heating the substrate to elevated temperatures.

FIG. 12 illustrates a schematic diagram of an example plasma processing apparatus with a remote plasma source according to some implementations. It will be understood that the plasma processing apparatus in FIG. 12 may be used to deposit a silicon-containing layer, and/or to etch the silicon-containing layer formed in the reaction chamber according to some embodiments. In some embodiments, a silicon-containing layer may be formed in the reaction chamber, followed by etching in the same reaction chamber using a remote plasma source without exposing the silicon-containing layer to ambient atmosphere. In some embodiments, a silicon-containing layer may be formed in the reaction chamber, followed by a plasma treatment operation using a densifying gas plasma using a remote plasma source.

The plasma processing apparatus 1200 includes a reaction chamber 1210 with a showerhead 1220. Inside the reaction chamber 1210, a substrate 1230 rests on a stage or pedestal 1235. In some embodiments, the pedestal 1235 can be fitted with a heating/cooling element. A controller 1240 may be connected to the components of the plasma processing apparatus 1200 to control the operation of the plasma processing apparatus 1200. For example, the controller 1240 may contain instructions for controlling process conditions for the operations of the plasma processing apparatus 1200, such as the temperature process conditions and/or the pressure process conditions. In some embodiments, the controller 1240 may contain instructions for controlling the flow rates of precursor gas, reactant gas, source gas, and/or carrier gas. The controller 1240 may contain instructions for changing the flow rate of the reactant gas, source gas, and/or carrier gas over time. The controller 1240 may contain instructions for controlling the chamber pressure, substrate temperature, RF power, exposure time, gas composition, and relative concentrations of the gas composition. A more detailed description of the controller 1240 is provided below.

During operation, gases or gas mixtures are introduced into the reaction chamber 1210 via one or more gas inlets coupled to the reaction chamber 1210. In some embodiments, two or more gas inlets are coupled to the reaction chamber 1210. A first gas inlet 1255 can be coupled to the reaction chamber 1210 and connected to a vessel 1250, and a second gas inlet 1265 can be coupled to the reaction chamber 1210 and connected to a remote plasma source 1260. In some embodiments, the second gas inlet 1265 may provide carrier gas to the reaction chamber 1210. In embodiments including remote plasma source, the delivery lines for the precursors and the radical species generated in the remote plasma source are separated. Hence, the precursors and the radical species do not substantially interact before reaching the substrate 1230. It will be understood that in some embodiments the gas lines may be reversed so that the vessel 1250 may provide precursor gas flow through the second gas inlet 1265 and the remote plasma source 1260 may provide ions and radicals through the first gas inlet 1255.

One or more radical species may be generated in the remote plasma source 1260 and configured to enter the reaction chamber 1210 via the second gas inlet 1265. Any type of plasma source may be used in remote plasma source 1260 to create the radical species. This includes, but is not limited to, an inductively coupled plasma (ICP) source, a capacitively coupled plasma (CCP) source, a microwave plasma source, a DC plasma source, and a laser-created plasma source. An example of a capacitively coupled plasma can be a radio frequency (RF) plasma. A high-frequency plasma can be configured to operate at 13.56 MHz or higher. An example of such a remote plasma source 1260 can be the GAMMAS, manufactured by Lam Research Corporation of Fremont, California. Another example of such a remote plasma source 1260 can be the Astron®, manufactured by MKS Instruments of Wilmington, Massachusetts, which can be operated at 440 kHz and can be provided as a subunit bolted onto a larger apparatus for processing one or more substrates in parallel. In some embodiments, a microwave plasma can be used as the remote plasma source 1260, such as the Astex®, also manufactured by MKS Instruments. A microwave plasma can be configured to operate at a frequency of 2.45 GHz. Gas species provided to the remote plasma source 1260 may include hydrogen, nitrogen, oxygen, carbon, or other gases as mentioned elsewhere herein. In certain embodiments, hydrogen is provided in a carrier such helium. As an example, hydrogen gas may be provided in a helium carrier at a concentration of about 1-50% volume hydrogen.

The precursors can be provided in vessel 1250 and can be supplied to the showerhead 1220 via the first gas inlet 1255. The showerhead 1220 distributes the precursors into the reaction chamber 1210 toward the substrate 1230. The substrate 1230 can be located beneath the showerhead 1220. It will be understood that the showerhead 1220 can have any suitable shape, and may have any number and arrangement of ports for distributing gases to the substrate 1230. The precursors can be supplied to the showerhead 1220 and ultimately to the substrate 1230 at a controlled flow rate.

The one or more radical species formed in the remote plasma source 1260 can be carried in the gas phase toward the substrate 1230. The one or more radical species can flow through a second gas inlet 1265 into the reaction chamber 1210. It will be understood that the second gas inlet 1265 need not be transverse to the surface of the substrate 1230 as illustrated in FIG. 12. In certain embodiments, the second gas inlet 1265 can be directly above the substrate 1230 or in other locations. The distance between the remote plasma source 1260 and the reaction chamber 1210 can be configured to provide mild reactive conditions such that the ionized species generated in the remote plasma source 1260 are substantially neutralized, but at least some radical species in low energy states or ground states remain in the environment adjacent to the substrate 1230. Such low energy state radical species are not recombined to form stable compounds. The distance between the remote plasma source 1260 and the reaction chamber 1210 can be a function of the aggressiveness of the plasma (e.g., determined in part by the source RF power level), the density of gas in the plasma (e.g., if there's a high concentration of hydrogen atoms, a significant fraction of them may recombine to form H₂ before reaching the reaction chamber 1210), and other factors. In some embodiments, the distance between the remote plasma source 1260 and the reaction chamber 1210 can be between about 1 cm and 30 cm, such as about 5 cm or about 15 cm.

In some embodiments, a co-reactant or reactant, which is not the primary silicon-containing precursor or a hydrogen radical, may be introduced. In some embodiments, the co-reactant or reactant may be introduced during deposition of the silicon-containing layer by thermal ALD or thermal CVD. In some embodiments, the co-reactant or reactant may be introduced during a plasma treatment operation for tuning a composition and/or density of the silicon-containing layer. In some embodiments, the co-reactant or reactant may be introduced during the remote plasma etch. In some embodiments, the plasma processing apparatus 1200 is configured to introduce the co-reactant or reactant through the second gas inlet 1265. In some cases, the co-reactant or reactant is at least partially converted to plasma. In some embodiments, the plasma processing apparatus 1200 is configured to introduce the co-reactant or reactant through the showerhead 1220 via the first gas inlet 1255. Examples of the co-reactant or reactant include oxygen, nitrogen, ammonia, carbon dioxide, carbon monoxide, and the like. The flow rate of the co-reactant or reactant can vary over time to produce a composition gradient in a graded film.

In some embodiments, a gas plasma flow may be generated from the remote plasma source 1260. A gas plasma flow from the remote plasma source 1260 may include ions, radicals, charged neutrals, and other reactive species of the reactant gas. For instance, the reactive species may include radical species of hydrogen, nitrogen, oxygen, carbon, or amine that may be supplied to the surface of the substrate 1230 for a remote plasma etching.

FIG. 13 illustrates a schematic diagram of an example plasma processing apparatus with a remote plasma source according to some implementations. It will be understood that the reaction chamber in FIG. 13 may be used to deposit a silicon-containing layer, treat the silicon-containing layer, and/or to etch the silicon-containing layer formed in the reaction chamber according to some embodiments. In some embodiments, a silicon-containing layer may be formed in the reaction chamber, followed by etching in the same reaction chamber using a remote plasma source without exposing the silicon-containing layer to ambient atmosphere. In some embodiments, a silicon-containing layer may be formed in the reaction chamber, followed by treatment in the same reaction chamber using a remote plasma without exposing the silicon-containing layer to ambient atmosphere.

The plasma processing apparatus 1300 includes a remote plasma source 1302 separated from a reaction chamber 1304. The remote plasma source 1302 is fluidly coupled with the reaction chamber 1304 via a gas distributor or showerhead 1306. In some embodiments, the showerhead 1306 includes an ion filter for filtering ions to limit ion bombardment damage to a substrate 1312. Radical species and/or ions are generated in the remote plasma source 1302, where the radical species may be supplied to the reaction chamber 1304. Precursors such as silicon-containing precursors are supplied to the reaction chamber 1304 through gas outlet 1308 positioned downstream from the remote plasma source 1302 and from the showerhead 1306.

The substrate 1312 is supported on a substrate support structure or wafer pedestal 1314. The wafer pedestal 1314 may be configured with lift pins or other movable support members to position the substrate 1312 within the deposition/etch zone 1310. The substrate 1312 may be moved to a position closer or farther from the showerhead 1306. The wafer pedestal 1314 is shown in FIG. 13 as having elevated the substrate 1312 within the deposition/etch zone 1310.

In some embodiments, the wafer pedestal 1314 includes an electrostatic chuck 1316. The electrostatic chuck 1316 includes one or more electrostatic clamping electrodes 1318 embedded within a body of the electrostatic chuck 1316. In some embodiments, the one or more electrostatic clamping electrodes 1318 may be coplanar or substantially coplanar. The electrostatic clamping electrodes 1318 may be powered by a DC power source or DC chucking voltage (e.g., between about 200 V to about 2000 V) so that the substrate 1312 may be retained on the electrostatic chuck 1316 by electrostatic attractive forces. Power to the electrostatic clamping electrodes 1318 may be provided via first electrical lines 1320. The electrostatic chuck 1316 may further include one or more heating elements 1322 embedded within the body of the electrostatic chuck 1316. The one or more heating elements 1322 may include resistive heaters. In some embodiments, the one or more heating elements 1322 are positioned below the one or more electrostatic clamping electrodes 1318. The one or more heating elements 1322 may be configured to heat the substrate 1312 to a temperature greater than about 450° C., greater than about 500° C., greater than about 550° C., greater than about 600° C., or greater than about 650° C. The one or more heating elements 1322 provide selective temperature control to the substrate 1312. Power to the one or more heating elements 1322 may be provided via second electrical lines 1324.

A coil 1328 is arranged around the remote plasma source 1302, where the remote plasma source 1302 includes an outer wall (e.g., quartz dome). The coil 1328 is electrically coupled to a plasma generator controller 1332, which may be used to form and sustain plasma within a plasma region 334 via inductively coupled plasma generation. In some embodiments, the plasma generator controller 1332 may include a power supply for supplying power to the coil 1328, where the power can be in a range between about 300 W and about 15 kW per station, or between about 1 kW and about 10 kW per station during plasma generation. In some embodiments, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 1334, radical species may continuously be generated using plasma excitation during a layer formation (e.g., film deposition) and/or remote plasma treatment.

In some embodiments, hydrogen radicals (H*), nitrogen radicals (N*), oxygen radicals (O*), carbon radicals (C*), amine radicals (NH*, NH₂*), or combinations thereof, are generated in the plasma region 1334 under approximately steady-state conditions during steady-state film deposition or a remote plasma treatment as controlled by the plasma generator controller 1332, though transients may occur at the beginning and end of film deposition and/or remote plasma etch. For example, hydrogen radicals may be generated in the plasma region 1334. In another example, two or more different types of radicals, such as nitrogen-containing radicals and hydrogen radicals, may be generated in the plasma region 1334. Though FIG. 13 shows nitrogen radicals (N*), amine radicals (NH*, NH₂*), and hydrogen radicals (H*), it will be understood that the foregoing radicals are illustrative only and that other radicals may be present additionally or alternatively to the radicals depicted in FIG. 13.

A supply of ions and radicals may be continuously generated within the plasma region 1334 while source gas is being supplied to the remote plasma source 1302. Ions generated in the plasma region 1334 may be filtered out by the ion filter of the showerhead 1306. That way, radicals generated in the plasma region 1334 may be supplied to the substrate 1312 in the reaction chamber 1304 while limiting ion bombardment. Filtering ions and/or photons may reduce substrate damage, undesirable re-excitation of molecules, and/or selective breakdown or decomposition of hydrocarbon precursors within the reaction chamber 1304.

Conditions in the remote plasma source 1302, including a composition of the source gas provided to the remote plasma source 1302 and RF power supplied to the coil 1328, may be controlled to optimize generation of desired radical species in the plasma region 1334. In some embodiments, the source gas may include an oxygen-containing reactant such as oxygen (O₂), ozone (O₃), carbon monoxide (CO), carbon dioxide (CO₂), or nitrogen dioxide (NO₂), nitrous oxide (N₂O), carbon-containing reactant such as acetylene (C₂H₂), ethylene (C₂H₄) or propene (C₃H₆), hydrogen-containing reactant such as hydrogen (H₂) or methane (CH₄), or nitrogen-containing reactant such as nitrogen (N₂), ammonia (NH₃), diazene (N₂H₂), or hydrazine (N₂H₄), or mixtures thereof. In some embodiments, the source gas may include hydrogen gas. By way of an example, hydrogen radicals may be generated in the plasma region 1334, where a source gas of hydrogen gas may be provided to the remote plasma source 1302 to provide a gas plasma flow including hydrogen radicals toward the substrate 1312 in the reaction chamber 1304.

In some embodiments, the source gas may be mixed with one or more additional gases. These one or more additional gases may be supplied to the remote plasma source 1302. In some embodiments, the source gas is mixed with one or more additional gases to form a gas mixture, where the one or more additional gases can include a carrier gas. Non-limiting examples of additional gases can include helium, neon, argon, krypton, and xenon. The one or more additional gases may support or stabilize steady-state plasma conditions within the remote plasma source 1302 or aid in transient plasma ignition or extinction processes. In FIG. 13, a source gas supply 1336 is fluidly coupled with the remote plasma source 1302 for supplying the source gas. For some embodiments, about 5 sccm to about 10000 sccm, or about 10 sccm to about 200 sccm of source gas may be supplied from a source gas supply 1336. In addition, an additional gas supply 1338 is fluidly coupled with the remote plasma source 1302 for supplying the one or more additional gases. While the embodiment in FIG. 13 depicts the gas mixture of the source gas and the one or more additional gases being introduced through separate gas outlets, it will be understood that the gas mixture may be introduced directly into the remote plasma source 1302. That is, a pre-mixed dilute gas mixture may be supplied to the remote plasma source 1302 through a single gas outlet.

Plasma-activated species 1342, such as excited nitrogen, hydrogen, carbon, oxygen, and/or amine radicals, flow out of the remote plasma source 1302 and into the reaction chamber 1304 via showerhead 1306. Plasma-activated species 1342 within the showerhead 1306 and within the reaction chamber 1304 are generally not subject to continued plasma excitation therein. The showerhead 1306 may have a plurality of gas ports to diffuse the flow of plasma-activated species 1342 into the reaction chamber 1304. In some embodiments, the plurality of gas ports may be mutually spaced apart. In some embodiments, the plurality of gas ports may be arranged as an array of regularly spaced apart channels or through-holes extending through a plate separating the remote plasma source 1302 and the reaction chamber 1304. The plurality of gas ports may smoothly disperse and diffuse exiting radicals (including plasma-activated species 1342) from the remote plasma source 1302 into the deposition/etch zone 1310 of the reaction chamber 1304 while filtering out ions.

Typical remote plasma sources are far removed from reaction vessels. Consequently, radical extinction and recombination, e.g., via wall collision events, may reduce active species substantially. In contrast, in some implementations, dimensions for the plurality of gas ports may be configured in view of the mean free path or gas flow residence time under typical processing conditions to aid the free passage of radicals into the reaction chamber 1304. In some implementations, openings for the plurality of gas ports may occupy between about 5% and about 20% of an exposed surface area of the showerhead 1306. In some implementations, the plurality of gas ports may each have an axial length to diameter ratio of between about 3:1 and 10:1 or between about 6:1 and about 8:1. Such aspect ratios may reduce wall-collision frequency for radical species passing through the plurality of gas ports while providing sufficient time for a majority of excited state radical species to relax to ground state radical species. In some implementations, dimensions of the plurality of gas ports may be configured so that the residence time of gases passing through the showerhead 1306 is greater than the typical energetic relaxation time of an excited state radical species.

With the delivery of the plasma-activated species 1342 to the reaction chamber 1304 from the showerhead 1306, precursors 1344 (or other process gases) may be introduced into the reaction chamber 1304. The precursors 1344 may include silicon-containing precursors such as silane. The precursors 1344 may be introduced via gas outlets 1308, where the gas outlets 1308 may be fluidly coupled with a precursor supply source 1340. The gas outlets 1308 may include mutually spaced apart openings so that the flow of the precursors 1344 may be introduced in a direction parallel with the plasma-activated species 1342 flowing from the showerhead 1306. In some embodiments, the gas outlets 1308 may be located downstream from the showerhead 1306. In some embodiments, the gas outlets 1308 are part of the showerhead 1306 such as in a dual-plenum showerhead. The dual-plenum showerhead may provide separate outlets/passages for the plasma-activated species 1342 and the precursors 1344 to avoid mixing in the showerhead 1306. That way, the precursors 1344 may flow into the reaction chamber 1304 via the showerhead 1306 without exposure to plasma in the remote plasma source 1302. The gas outlets 1308 may be located upstream from the deposition/etch zone 1310 and the substrate 1312. The deposition/etch zone 1310 is located within the interior of the reaction chamber 1304 between the gas outlets 1308 and the substrate 1312.

In film deposition process, a substantial fraction of the precursors 1344 may be prevented from mixing with plasma-activated species 1342 in the showerhead 1306 or adjacent to the showerhead 1306. In some embodiments, precursors 1344 may be delivered to the substrate 1312 in dose phases of ALD cycles separate from plasma-activated species 1342 delivered to the substrate 1312 during plasma exposure phases of the ALD cycles. Adsorbed precursors 1344 may react with radicals of the plasma-activated species 1342 during plasma exposure phases of the ALD cycles to deposit film. In some embodiments, precursors 1344 may be delivered to the substrate 1312 in a continuous manner to interact with plasma-activated species 1342 in a deposition/etch zone 1310 to deposit film by CVD. In some embodiments, the plasma-activated species 1342 may be delivered to the substrate 1312 without delivery of the precursors 1344 to etch film.

Gases may be removed from the reaction chamber 1304 via an outlet 1348 that is fluidly coupled to a pump (not shown). Thus, radical species or purge gases may be removed from the reaction chamber 1304.

In some embodiments, a thermal shield (not shown) may be positioned underneath the wafer pedestal 1314. The thermal shield serves as a thermal insulator under the wafer pedestal 1314 to mitigate heat loss via thermal radiation, thereby reducing the amount of power needed to maintain the wafer pedestal 1314 at a particular elevated temperature and also preventing other components within the reaction chamber 1304 from overheating due to excess heat radiated from the wafer pedestal 1314. For example, the thermal shield may be radially offset from the stem 1326 and may have a thin annular-shaped body with a high view factor relative to the underside of the electrostatic chuck 1316. Thus, the annular-shaped thermal shield may reduce radiative heat loss from the wafer pedestal 1314.

The electrostatic chuck 1316 of the wafer pedestal 1314 may chuck/dechuck the substrate 1312 in the plasma processing apparatus 1300 that is configured to operate at high temperatures. Such high temperatures may be greater than about 350° C., greater than about 400° C., greater than about 450° C., greater than about 500° C., or greater than about 550° C.

In some embodiments, a controller 1350 (e.g., system controller) is in operative communication with the plasma processing apparatus 1300. In some embodiments, the controller 1350 includes a processor system 1352 (e.g., microprocessor) configured to execute instructions held in a data system 1354 (e.g., memory). In some embodiments, the controller 1350 may be in communication with the plasma generator controller 1332 to control plasma parameters and/or conditions in the remote plasma source 1302. In some embodiments, the controller 1350 may be in communication with the wafer pedestal 1314 to control pedestal elevation, electrostatic chucking and dechucking, and temperature. In some embodiments, the controller 1350 may control other processing conditions, such as RF power settings, frequency settings, duty cycles, pulse times, pressure within the reaction chamber 1304, pressure within the remote plasma source 1302, gas flow rates from the source gas supply 1336, gas flow rates from the additional gas supply 1338 and other sources, temperature of the wafer pedestal 1314, and temperature of the reaction chamber 1304, among other processing conditions.

The controller 1350 may contain instructions for controlling process conditions for the operation of the plasma processing apparatus 1300. The controller 1350 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 1350 or they may be provided over a network.

In certain embodiments, the controller 1350 controls all or most activities of the plasma processing apparatus 1300 described herein. For example, the controller 1350 may control all or most activities of the plasma processing apparatus 1300 associated with film deposition, film treatment, and/or a remote plasma etch. The controller 1350 may execute system control software including sets of instructions for controlling the timing, gas composition, gas flow rates, chamber pressure, chamber temperature, RF power levels, substrate position, substrate temperature, and/or other parameters. Other computer programs, scripts, or routines stored on memory devices associated with the controller 1350 may be employed in some embodiments. In a multi-station reactor, the controller 1350 may comprise different or identical instructions for different apparatus stations, thus allowing the apparatus stations to operate either independently or synchronously.

In some embodiments, the controller 1350 may include instructions configured to perform operations such as conformally depositing a silicon-containing film in recessed features of the substrate 312, and exposing the substrate 1312 to plasma-activated species 1342 generated in the remote plasma source 1302 to etch the silicon-containing film to at least one of a desired depth and desired profile. In some embodiments, exposing the substrate 1312 to the plasma-activated species 1342 to etch the silicon-containing film to the desired depth and/or desired profile occurs by modulating one or more of the following parameters: chamber pressure, substrate temperature, time of exposure, gas composition of the remote plasma, relative concentrations of the gas composition, and RF power.

In some embodiments, the controller 1350 may include instructions configured to perform operations such as causing the formation of a silicon-containing film over the substrate 1312 without igniting a plasma at a substrate temperature of less than about 700° C., and causing the silicon-containing film to be treated using a densifying gas plasma. The silicon-containing film may be deposited using thermal ALD and/or thermal CVD. The controller 1350 may include instructions further configured to modulate at least one of a silicon-containing precursor, a reactant, or process conditions during plasma treatment to vary at least the composition of or density of the silicon-containing film.

In some embodiments, the plasma processing apparatus 1300 may include a user interface associated with controller 1350. The user interface may include a display screen, graphical software displays of the plasma processing apparatus 1300 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the controller 1350. The signals for controlling the process are output on the analog and digital output connections of the processing system.

Broadly speaking, the controller 1350 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 1350 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., amorphous silicon), surfaces, circuits, and/or dies of a wafer.

The controller 1350, in some embodiments, may be a part of or coupled to a computer that is integrated with, coupled to the system, otherwise networked to the system, or a combination thereof. For example, the controller 1350 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 1350 receives instructions in the form of data, which specify parameters for each of the processing steps to be performed during one or more operations. It should be understood that the parameters may be specific to the type of process to be performed and the type of tool that the controller 1350 is configured to interface with or control. Thus, as described above, the controller 1350 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

### Definitions and Precursors

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₄ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane n-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₄ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₄ alkyl (e.g., -L-SO₂—R, in which each of L and R is, independently, C₁₋₆ alkyl); (9) aryl; (10) amino (e.g., —NR¹R² where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). Tn some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —C4 group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

In various embodiments, the silicon-containing precursor is a silane. Silanes include but are not limited to substituted and unsubstituted silanes, halosilanes, aminosilanes, organosilanes, alkylsilanes, alkylaminosilanes, and alkylhalosilanes. In particular embodiments, the silicon-containing precursor includes a halosilane precursor. In particular embodiments, the silicon-containing precursor includes an aminosilane precursor.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamino)silane (DIPAS), bis(diethylamino)silane (BDEAS), and the like. A further example of an aminosilane is trisilylamine (N(SiH₃)₃). In one example, the silicon-containing precursor is DIPAS. In another example, the silicon-containing precursor is BTBAS. In some embodiments, the silane precursor is a siloxane precursor. In some embodiments, the aminosilane is a siloxane. The siloxane precursor may be a disiloxane, or a trisiloxane, or a cyclic siloxane, or a tetrasiloxane. Cyclic siloxanes may include cyclotetrasiloxanes, such as 2,4,6,8-tetramethylcyclotetrasiloxane (TMCTS), octamethylcyclotetrasiloxane (OMCTS), and heptamethylcyclotetrasiloxane (HMCTS). Other cyclic siloxanes can also include but are not limited to cyclotrisiloxanes and cyclopentasiloxanes. Tn some embodiments, the silicon-containing deposition precursor is 1-dimethylamino-1,1,5,5,5,-pentamethyl disiloxane. In some embodiments, the siloxane may have a three-dimensional or caged structure. Caged siloxanes have silicon atoms bridged to one another via oxygen atoms to form a polyhedron or any 3-D structure. An example of a caged siloxane precursor molecule is silsesquioxane. Caged siloxane structures are described in further detail in commonly owned U.S. Pat. No. 6,576,345 to Cleemput et al., which is incorporated by reference herein in its entirety for all purposes. In some embodiments, the siloxane may be linear. Linear siloxanes may include, but are not limited to, disiloxanes, such as pentamethyldisiloxane (PMDSO), tetramethyldisiloxane (TMDSO), and hexamethyl trisiloxane. PMDSO and TMDSO may be used to form SiOC films.

A silicon-containing precursor can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R)(H)₂Si(NR″₂), wherein R′ and R″ can be any described herein. In one embodiment, the precursor has a formula of (R)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The precursor can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

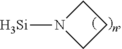

in which the heterocyclyl group can be optionally substituted (e.g., with any substituent described herein as a substitution for alkyl), and wherein n is 1, 2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

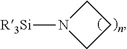

in which the heterocyclyl group can be optionally substituted (e.g., with any substituent described herein as a substitution for alkyl); each R′ can independently be any described herein; and wherein n is 1, 2, 3, 4, or 5.

In some instances, the precursor can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the precursor has a formula of (R″₂N)(R′)₂Si—Si(R′)₂(NR″₂), wherein R′ and R″ can be any described herein. In another embodiment, the precursor has a formula of (R″₂N)₂(R′)Si—Si(R′)(NR″₂)₂, wherein R′ and R″ can be any described herein. In yet another embodiment, the precursor has a formula of (R″₂N)₃Si—Si(NR″₂)₃, wherein each R″ can independently be any described herein.

The precursor can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the precursor has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(H)₃₋ₓSi—NR—Si(H)₃₋ₓ(NR″₂)ₓ, wherein R, R′, and R″ can be any described herein.

The precursor can include a combination of R′ groups with a linker having a heteroatom. In one instance, the precursor has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of (R″₂N)(R′)₂Si-L-Si(R′)₂(NR″₂)ₓ, wherein L, R′, and R″ can be any described herein.

The precursor can include heterocyclic groups including the silicon and nitrogen atoms. In one embodiment, the precursor has a formula of

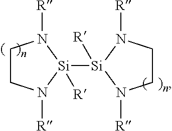

wherein R′ and R″ can be any described herein, and wherein n is 1, 2, 3, or 4.

In another embodiment, the precursor has a formula of

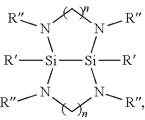

wherein R′ and R″ can be any described herein, and wherein n is 1, 2, 3, or 4. In yet another embodiment, the precursor has a formula of

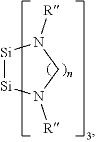

in which each R″ can independently be any described herein; and wherein n is 1, 2, 3, or 4.
In another embodiment, the precursor has a formula of

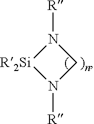

wherein R′ and R″ can be any described herein, and wherein n is 1, 2, 3, or 4. In yet another embodiment, the precursor has a formula of

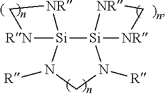

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHRA), H₂Si(NHR^{Ak}₂)₂, (R^{Ak})(H)Si(NR^{Ak}₂)₂, HSi(NH₂)(NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇Si, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMes[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropylaminosilane (SiH₃[NiPmPr]); N-methylcyclohexylaminosilane (SiH₃[NMeCy]); N-ethylcyclohexylaminosilane (SiH₃[NEtCy]); allylphenylaninosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]₂ or BDMAS); bis(dimethylamino) methylsilane (SiMeH[NMe₂]₂); bis(dimethylamino)dimethylsilane (SiMe₂[NMe₂]₂ or BDMADMS); bis(dimethylamino)diethylsilane (SiEt₂[NMe₂]₂); bis(dimethylamino) methylvinylsilane (SiMeVi[NMe₂]₂); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino)diethylsilane (SiEt₂[NMeEt]₂); bis(ethylmethylamino) methylvinylsilane (SiMeVi[NMeEt]₂); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino)diethylsilane (SiEt₂[NEt₂]₂); bis(iso-propylamino) dimethylsilane (SiMe₂[NHiPr]₂); bis(iso-propylamino)diethylsilane (SiEt₂[NHiPr]₂); bis(iso-propylamino)methylvinylsilane (SiMeVi[NHiPr]₂); bis(di-iso-propylamino)silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]₃ or 3DMAS); tris(dimethylamino)phenylsilane (SiPh[NMe₂]₃); tris(dimethylamino) methylsilane (SiMe[NMe₂]₃); tris(dimethylamino)ethylsilane (SiEt[NMe₂]₃); tris(ethylmethylamino)silane (SiH[NEtMe]₃); tris(diethylamino)silane (SiH[NEt₂]₃); tris(iso-propylamino)silane (SiH[NHiPr]₃. C₉H₂₅N₃Si, or TIPAS); tris(dimethylamino)silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino) disilane ([Et₂N]₂EtSi-SiEt[NEt₂]₂); 1,2-dimethyl-tetrakis(dimethylamino)disilane ([Me₂N]₂MeSi-SiMe[NMe₂]₂); 1,2-dimethyl-tetrakis(diethylamino)disilane ([Et₂N]₂MeSi-SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

### CONCLUSION

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of processing a substrate, the method comprising:
conformally depositing a silicon-containing film in one or more recessed features of the substrate; and
etching at least a portion of the silicon-containing film to at least one of a desired depth and desired profile by exposing the substrate to a remote plasma.

2. The method of claim 1, wherein the silicon-containing film comprises an amorphous silicon layer.

3. The method of claim 1, wherein the silicon-containing film comprises silicon oxide, silicon nitride, silicon carbide, silicon oxycarbide, silicon carbonitride, silicon oxynitride, or silicon oxycarbonitride.

4. The method of claim 3, wherein conformally depositing the silicon-containing film comprises:
flowing a silicon-containing precursor to adsorb on surfaces of the substrate;
thermally decomposing the silicon-containing precursor to form an amorphous silicon layer; and
exposing the amorphous silicon layer to plasma to convert the amorphous silicon layer to silicon oxide, silicon nitride, silicon carbide, silicon oxycarbide, silicon carbonitride, silicon oxynitride, or silicon oxycarbonitride.

5. The method of claim 1, wherein conformally depositing the silicon-containing film comprises:
depositing the silicon-containing film by thermal ALD or thermal CVD; and
treating the silicon-containing film with a densifying gas plasma.

6. The method of claim 1, wherein the at least one of the desired depth and desired profile of the etch is based on one or more of the following etch parameters: chamber pressure, substrate temperature, exposure time, gas composition, relative concentrations of the gas composition, and RF power.

7. A method of processing a substrate, the method comprising:
flowing, into a reaction chamber, a silane-based precursor to adsorb in one or more recessed features of the substrate, wherein the substrate is at an elevated temperature to thermally decompose the silane-based precursor and conformally deposit an amorphous silicon layer in the one or more recessed features of the substrate;
generating, in a remote plasma chamber upstream of the reaction chamber, a remote plasma comprising radicals of hydrogen, halides, hydrocarbons, fluorocarbons, or combinations thereof; and
exposing, in the reaction chamber, the substrate to the remote plasma to etch at least a portion of a silicon-containing layer in the one or more recessed features to at least one of a desired depth and desired profile by modulating one or more of the following etch parameters: chamber pressure, substrate temperature, exposure time, gas composition of the remote plasma, relative concentrations of the gas composition, and RF power.

8. A method of processing a substrate housed in a process chamber, the method comprising:
introducing a silicon-containing precursor and a reactant to the process chamber at a substrate temperature less than about 700° C. to form a silicon-containing film over the substrate without igniting a plasma;
after forming the silicon-containing film, performing a plasma treatment operation, the plasma treatment operation comprising:
stopping flow of the silicon-containing precursor and the flow of the reactant;
introducing a densifying gas into the process chamber; and
igniting a plasma to treat the silicon-containing film; and
modulating at least one of the silicon-containing precursor, the reactant, or process conditions during the plasma treatment operation to vary at least the composition of or density of the silicon-containing film to form a treated silicon-containing film.

9. The method of claim 8, further comprising:
etching at least a portion of the treated silicon-containing film to at least one of a desired depth and desired profile by exposing the substrate to a remote plasma.

10. An apparatus for processing substrates, the apparatus comprising:
one or more process chambers, each process chamber comprising a chuck;
one or more gas inlets into the process chambers and associated flow-control hardware; and
a controller having at least one processor and a memory, wherein the at least one processor and the memory are communicatively connected with one another, the at least one processor is at least operatively connected with the flow-control hardware, and the memory stores computer-executable instructions for controlling the at least one processor to at least control the flow-control hardware to:
cause formation of a silicon-containing film over the substrate without igniting a plasma at a substrate temperature of less than about 700° C.; and
cause the silicon-containing film to be treated using a densifying gas plasma.
